(19) United States
(12) Patent Application Publication
(10) Pub. No.: US 2010/0244185 A1
(43) Pub. Date: Sep. 30, 2010

(54) SEMICONDUCTOR DEVICE, SINGLE-CRYSTAL SEMICONDUCTOR THIN FILM-INCLUDING SUBSTRATE, AND PRODUCTION METHODS THEREOF

(75) Inventors: Yutaka Takafuji, Osaka-shi (JP); Yasumori Fukushima, Osaka-shi (JP); Kenshi Tada, Osaka-shi (JP); Kazuo Nakagawa, Osaka-shi (JP); Shin Matsumoto, Osaka-shi (JP); Kazuhide Tomiyasu, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/742,932

(22) PCT Filed: Oct. 22, 2008
(86) PCT No.: PCT/JP2008/069154

§ 371 Date: May 14, 2010

(30) Foreign Application Priority Data
Dec. 27, 2007 (JP) 2007-337921

(51) Int. Cl. H01L 27/12; H01L 21/762; H01L 21/86

(52) U.S. Cl. 257/507; 438/458; 257/E21.568; 257/E21.704; 438/479; 257/E27.112

(57) ABSTRACT

The present invention provides a semiconductor device, a single-crystal semiconductor thin film-including substrate, and production methods thereof, each allowing single-crystal semiconductor thin film-including single-crystal semiconductor elements produced by being transferred onto a low heat resistant insulating substrate to have enhanced transistor characteristics.

The present invention is a production method of a semiconductor device including single-crystal semiconductor thin film-including single-crystal semiconductor elements on an insulating substrate,
the production method including the successive steps of a first heat treatment step and a second heat treatment step,
wherein in the first heat treatment step,
a single-crystal semiconductor thin film undergoes a heat treatment at lower than 650° C.,
the single-crystal semiconductor thin film containing a doped impurity and including at least part of each one of single-crystal semiconductor elements,
the single-crystal semiconductor thin film bonded to an insulating substrate, and
in the second heat treatment step,
the single-crystal semiconductor thin film undergoes a heat treatment at 650° C. or higher for a time shorter than a treatment time in the first heat treatment step.

### TECHNICAL FIELD

The present invention is directed to semiconductor devices, single-crystal semiconductor thin film-including substrates, and production methods thereof. More particularly, the present invention is directed to a semiconductor device and a single-crystal semiconductor thin film-including substrate each preferably used in display devices such as an LCD (liquid crystal display) device and an organic EL display device, and to production methods thereof.

### BACKGROUND ART

Semiconductor devices are electronic devices including active elements exploiting electric properties of semiconductor materials. Such semiconductor devices have been widely used in audio equipment, communication equipment, computers, electric appliances, and the like. Particularly, semiconductor devices including a three-terminal active element such as a MOS (metal oxide semiconductor) thin film transistor (hereinafter, also referred to as a “TFT”) are used as a pixel switching element arranged in each pixel, a pixel control circuit, and the like, in display devices such as an active matrix liquid crystal display device (hereinafter, also referred to as an “LC display”) and an organic electroluminescent display device (hereinafter, also referred to as a “organic EL display”).

Single-crystal semiconductor thin film-including substrates, which include a single-crystal semiconductor thin film on an insulating substrate, particularly, a SOI (silicon on insulator) substrate, which includes a single-crystal Si layer on an insulating layer, is being actively researched now.

For example, Non-patent Documents 1 and 2 relate to the Smart-Cut process developed by Bruel. According to the Smart-Cut process, a single-crystal silicon layer is transferred onto a substrate in the following manner: hydrogen or rare gas ions are implanted into a bulk silicon (Si) wafer; this wafer is attached to another substrate; a heat treatment is performed for cleavage of the hydrogen-implanted layer to cleave the wafer.

With respect to transfer of a semiconductor substrate to a substrate, a technology of bonding flat and hydrophilic oxide films to each other is being developed.

Further, with respect to transfer of a semiconductor substrate to a display device substrate, large-size substrates for active matrix display devices including single-crystal Si thin films closely arranged over the entire glass substrate in a tile pattern or disposed at portions of the glass substrate are also being developed.

For example, Non-patent Document 3 relates to thermal donor formation in Si.

### [Non-Patent Document 1]

M. Bruel (1995), “Silicon on insulator material technology”, Electronics Letters, vol. 31, No. 14, p. 1201 to 1202, U.S.

### [Non-Patent Document 2]

Michel Bruel, and three others (1997), “Smart-cut: A New Silicon On Insulator Material Technology Based on Hydrogen Implantation and Wafer Bonding,” Japanese Journal of Applied Physics, vol. 36, No. 3B, p. 1636 to 1641, Japan.

### [Non-Patent Document 3]

H. J. Stein, S. K. Hahn (1994), “Hydrogen introduction and hydrogen-enhanced thermal donor formation in silicon,” Journal of Applied Physics, vol. 75, No. 7, p. 3477 to 3484, U.S.

### DISCLOSURE OF INVENTION

According to the conventional technology involving only one transfer process, the implanted hydrogen ions might cause thermal donor formation or inactivation of acceptor boron (B) to deteriorate transistor characteristics. This occurs not when LSI technology allowing high-temperature heat treatments is employed but when low to medium temperature heat treatments are performed due to low heat resistance of glass substrates.

Further, surface roughness of the single-crystal Si thin film, or uneven thickness of the film possibly causes a reduction or variation in transistor characteristics.

The present invention has been made in view of the above-mentioned state of the art. The present invention has an object to provide a semiconductor device, a single-crystal semiconductor thin film-including substrate, and production methods thereof, each allowing single-crystal semiconductor thin film-including single-crystal semiconductor elements produced by being transferred onto a low heat resistant insulating substrate to have enhanced transistor characteristics.

The present inventors made various investigations on the above-mentioned semiconductor device, single-crystal semiconductor thin film-including substrate, and production methods thereof, and noted heat treatments for the single-crystal semiconductor thin film. The inventors found that curing of defects in the single-crystal semiconductor thin film, and suppression of thermal donor formation and activation of inactivated boron in the thin film are allowed when the single-crystal semiconductor thin film bonded to the low heat-resistant insulating substrate undergoes a heat treatment at lower than 650° C. for a predetermined time and further undergoes a heat treatment at 650° C. or higher for a time shorter than the predetermined time even if the thin film is formed by being separated from a semiconductor substrate by cleavage of a cleavage substance containing hydrogen and/or rare gas ions-implanted layer formed in the semiconductor substrate. As a result, the above-mentioned problems have been admirably solved, leading to completion of the present invention.

The present invention relates to a production method of a semiconductor device including single-crystal semiconductor thin film-including single-crystal semiconductor elements on an insulating substrate,

the production method including the successive steps of a first heat treatment step and a second heat treatment step,

wherein in the first heat treatment step,

a single-crystal semiconductor thin film undergoes a heat treatment at lower than 650° C.,

the single-crystal semiconductor thin film containing a doped impurity and including at least part of each one of single-crystal semiconductor elements,

the single-crystal semiconductor thin film bonded to an insulating substrate, and

in the second heat treatment step,

the single-crystal semiconductor thin film undergoes a heat treatment at 650° C. or higher for a time shorter than a treatment time in the first heat treatment step (hereinafter, also referred to as a “production method of the semiconductor device of the present invention”).

According to this production method, curing of defects in the single-crystal semiconductor thin film, and suppression of thermal donor formation and activation of inactivated acceptor (preferably, boron) in the thin film are allowed even if the thin film is formed by being separated from a semiconductor substrate by cleavage of a cleavage substance containing hydrogen and/or rare gas ions-implanted layer formed in the semiconductor substrate. As a result, the transistor characteristics can be improved. According to the production method of the present invention, the characteristics of the single-crystal semiconductor elements can be optimized by adjusting the treatment temperature and time in each of the first and second heat treatment steps.

Thus, the present invention is also a production method of a semiconductor device, including the successive steps of a first heat treatment step and a second heat treatment step,

wherein in the first heat treatment step,

a single-crystal semiconductor thin film undergoes a heat treatment at lower than 650° C.,

the single-crystal semiconductor thin film containing a doped impurity and including at least part of each one of single-crystal semiconductor elements,

the single-crystal semiconductor thin film bonded to an insulating substrate, and

in the second heat treatment step,

the single-crystal semiconductor thin film undergoes a heat treatment at 650° C. or higher for a time shorter than a treatment time in the first heat treatment step.

The production method of the semiconductor device of the present invention is not especially limited as long as it involves the above-mentioned first and second heat treatment steps.

The present invention is also a production method of a single-crystal semiconductor thin film-including substrate including an insulating substrate and a single-crystal semiconductor thin film formed on the insulating substrate,

the production method including the successive steps of a first heat treatment step and a second heat treatment step,

wherein in the first heat treatment step,

a single-crystal semiconductor thin film bonded to an insulating substrate undergoes a heat treatment at lower than 650° C., and

in the second heat treatment step,

the single-crystal semiconductor thin film undergoes a heat treatment at 650° C. or higher for a time shorter than a treatment time in the first heat treatment step (hereinafter, also referred to as a “production method of the single-crystal semiconductor thin film-including substrate of the present invention”).

Also according to this production method, curing of defects in the single-crystal semiconductor thin film, and suppression of thermal donor formation and activation of inactivated acceptor (preferably, boron) in the thin film are allowed even if the thin film is formed by being separated from a semiconductor substrate by cleavage of a cleavage substance containing hydrogen and/or rare gas ions-implanted layer formed in the semiconductor substrate. According to the production method of the single-crystal semiconductor thin film-including substrate of the present invention, the hydrogen concentration in the single-crystal semiconductor thin film can be optimized by adjusting the treatment temperature and time in each of the first and second heat treatment steps, and further defects in the thin film can be cured.

Thus, the present invention is also a production method of a single-crystal semiconductor thin film-including substrate, the method including the successive steps of a first heat treatment step and a second heat treatment step,

wherein in the first heat treatment step,

a single-crystal semiconductor thin film bonded to an insulating substrate undergoes a heat treatment at lower than 650° C., and

in the second heat treatment step,

the single-crystal semiconductor thin film undergoes a heat treatment at 650° C. or higher for a time shorter than a treatment time in the first heat treatment step.

The production method of the single-crystal semiconductor thin film-including substrate of the present invention may or may not include other steps as long as it involves the above-mentioned first and second heat treatment steps.

According to another embodiment of the above-mentioned production method of the semiconductor device, the production method further including: before the first heat treatment step,

a bonding step;

a semiconductor substrate-separating step; and

an element-dividing step, in this order,

wherein in the bonding step,

a semiconductor substrate is bonded to the insulating substrate,

the semiconductor substrate containing the doped impurity and including: the at least part of each one of single-crystal semiconductor elements; and a cleavage layer including an implanted cleavage substance containing at least one of hydrogen ion and rare gas ion;

in the semiconductor substrate-separating step,

the semiconductor substrate is separated by cleavage of the cleavage layer by a heat treatment;

in the element-dividing step,

a remaining portion of the semiconductor substrate bonded to the insulating substrate is thinned to give the single-crystal semiconductor thin film, and the semiconductor elements are divided;

in the first heat treatment step,

the single-crystal semiconductor thin film and the insulating substrate undergo the heat treatment; and

in the second heat treatment step,

the single-crystal semiconductor thin film and the insulating substrate undergo the heat treatment.

Thus, while the advantages of the present invention can be sufficiently exhibited, the semiconductor device including the thinned single-crystal semiconductor thin film-including single-crystal semiconductor elements can be more easily produced.

According to another embodiment of the above-mentioned production method of the semiconductor device, the production method further includes: before the first heat treatment step,

an element-forming step;

a doping step;

an activation step;

a flattening step;

a cleavage layer-forming step;

a bonding step;

a semiconductor substrate-separating step; and

a element-dividing step, in this order,

wherein in the element-forming step,

the at least part of each one of semiconductor elements is formed on a semiconductor substrate;

in the doping step,

the semiconductor substrate is doped with the impurity;

in the activation step,

the impurity in the semiconductor substrate is activated by a heat treatment;

in the flattening step,

a flattening layer is formed on the semiconductor element side-surface of the semiconductor substrate;

in the cleavage layer-forming step,

a cleavage layer is formed by implanting a cleavage substance containing at least one of hydrogen ion and rare gas ion into the semiconductor substrate at a predetermined depth through the flattening layer;

in the bonding step,

the flattening layer of the semiconductor substrate is bonded to the insulating substrate;

in the semiconductor substrate-separating step,

the semiconductor substrate is separated by cleavage of the cleavage layer by a heat treatment;

in the element-dividing step,

a remaining portion of the semiconductor substrate bonded to the insulating substrate is thinned to give the single-crystal semiconductor thin film, and the semiconductor elements are divided;

in the first heat treatment step,

the single-crystal semiconductor thin film and the insulating substrate undergo the heat treatment; and

in the second heat treatment step,

the single-crystal semiconductor thin film and the insulating substrate undergo the heat treatment.

Thus, while the advantages of the present invention can be sufficiently exhibited, the semiconductor device including the thinned single-crystal semiconductor thin film-including single-crystal semiconductor elements can be more easily produced.

According to another embodiment of the above-mentioned production method of the single-crystal semiconductor thin film-including substrate, the production method further includes: before the first heat treatment step,

a bonding step;

a semiconductor substrate-separating step; and

a thinning step in this order,

wherein in the bonding step,

a semiconductor substrate including a cleavage layer containing an implanted cleavage substance containing at least one of hydrogen ion and rare gas ion is bonded to the insulating substrate;

in the semiconductor substrate-separating step,

the semiconductor substrate is separated by cleavage of the cleavage layer by a heat treatment;

in the thinning step,

a remaining portion of the semiconductor substrate bonded to the insulating substrate is thinned to give the single-crystal semiconductor thin film;

in the first heat treatment step,

the single-crystal semiconductor thin film and the insulating substrate undergo the heat treatment; and

in the second heat treatment step,

the single-crystal semiconductor thin film and the insulating substrate undergo the heat treatment.

Thus, while the advantages of the present invention can be sufficiently exhibited, the thinned single-crystal semiconductor thin film can be more easily produced.

According to another embodiment of the above-mentioned production method of the single-crystal semiconductor thin film-including substrate, the production method further includes: before the first heat treatment step,

a cleavage layer-forming step;

a bonding step;

a semiconductor substrate-separating step; and

a thinning step in this order,

wherein in the cleavage layer-forming step,

a cleavage layer is formed by implanting a cleavage substance containing at least one of hydrogen ion and rare gas ion into a semiconductor substrate at a predetermined depth;

in the bonding step,

the semiconductor substrate is bonded to the insulating substrate;

in the semiconductor substrate-separating step,

the semiconductor substrate is separated by cleavage of the cleavage layer by a heat treatment;

in the thinning step,

a remaining portion of the semiconductor substrate bonded to the insulating substrate is thinned to give the single-crystal semiconductor thin film;

in the first heat treatment step,

the single-crystal semiconductor thin film and the insulating substrate undergo the heat treatment; and

in the second heat treatment step,

the single-crystal semiconductor thin film and the insulating substrate undergo the heat treatment.

Thus, while the advantages of the present invention can be sufficiently exhibited, the single-crystal semiconductor thin film-including substrate, which includes the thinned single-crystal semiconductor thin film on the insulating substrate, can be more easily produced.

The first and second heat treatment steps are performed with or without a time interval therebetween.

The first and second heat treatment steps are performed by the same or different apparatuses (means), but preferably by different apparatuses (means). More specifically, it is preferable that the heat treatment in the first heat treatment step is furnace annealing and that the heat treatment in the second heat treatment is RTA (rapid thermal annealing).

According to another embodiment of the above-mentioned production method of the semiconductor device, it is preferable that the production method further includes:

a p-type impurity doping step or p-type impurity doping steps of doping a semiconductor substrate on which the single-crystal semiconductor thin film is to be formed with a p-type impurity; and

an n-type impurity doping step or n-type impurity doping steps of doping the semiconductor substrate with an n-type impurity,

wherein in the p-type impurity doping step or at least one of the p-type impurity doping steps,

the semiconductor substrate is doped with the p-type impurity at a concentration higher than a finally needed impurity concentration, and

in the n-type impurity doping step or at least one of the n-type impurity doping steps,

the semiconductor substrate is doped with the n-type impurity at a concentration lower than a finally needed impurity concentration.

According to this embodiment, the advantages of the present invention can be more effectively exhibited.

Thus, the production method may further include at least one p-type impurity doping step of doping the semiconductor substrate with a p-type impurity, and at least one n-type impurity doping step of doping the semiconductor substrate with an n-type impurity. In the at least one p-type impurity doping step, the semiconductor substrate is doped with the p-type impurity at a concentration higher than a finally needed impurity concentration, and in the at least one n-type impurity doping step, the semiconductor substrate is doped with the n-type impurity at a concentration lower than a finally needed impurity concentration.

The present invention is also a production method of a semiconductor device including single-crystal semiconductor thin film-including single-crystal semiconductor elements on an insulating substrate, wherein the production method includes:

a p-type impurity doping step or p-type impurity doping steps of doping a semiconductor substrate on which the single-crystal semiconductor thin film is to be formed with a p-type impurity; and

an n-type impurity doping step or n-type impurity doping steps of doping the semiconductor substrate with an n-type impurity,

wherein in the p-type impurity doping step or at least one of the p-type impurity doping steps,

the semiconductor substrate is doped with the p-type impurity at a concentration higher than a finally needed impurity concentration, and

in the n-type impurity doping step or at least one of the n-type impurity doping steps,

the semiconductor substrate is doped with the n-type impurity at a concentration lower than a finally needed impurity concentration, or

a production method of a semiconductor device including single-crystal semiconductor thin film-including single-crystal semiconductor elements on an insulating substrate,

wherein the production method include: at least one p-type impurity doping step of doping the semiconductor substrate with a p-type impurity, and at least one n-type impurity doping step of doping the semiconductor substrate with an n-type impurity,

in the at least one p-type impurity doping step,

the semiconductor substrate is doped with the p-type impurity at a concentration higher than a finally needed impurity concentration, and

in the at least one n-type impurity doping step,

the semiconductor substrate is doped with the n-type impurity at a concentration lower than a finally needed impurity concentration.

It is more preferable that in the p-type impurity doping step or each of the p-type impurity doping steps,

the semiconductor substrate is doped with the p-type impurity at a concentration higher than a finally needed impurity concentration; and

in the n-type impurity doping step or each of the n-type impurity doping steps,

the semiconductor substrate is doped with the n-type impurity at a concentration lower than a finally needed impurity concentration.

Further, it is more preferable that in the p-type impurity doping step or at least one of the p-type impurity doping steps,

the semiconductor substrate is doped with the p-type impurity at a concentration five times or higher than a finally needed impurity concentration.

According to these embodiments, the advantages of the present invention can be still more effectively exhibited.

Thus, according to the production method of the semiconductor device, in at least one p-type impurity doping step, the semiconductor substrate may be doped with the p-type impurity at a concentration five times higher than a finally needed impurity concentration.

It is still more preferable that in the p-type impurity doping step or each of the p-type impurity doping steps, the semiconductor substrate is doped with the p-type impurity at a concentration five times or higher than a finally needed impurity concentration.

According to this embodiment, the advantages of the present invention can be particularly effectively exhibited.

It is preferable that the impurity contains boron. According to this, the advantages of the present invention can be more effectively exhibited.

According to the production method of the single-crystal semiconductor thin film-including substrate, it is preferable that the production method further includes:

a strained semiconductor layer-including substrate-forming step;

a cleavage layer-forming step;

a bonding step;

a strained semiconductor layer-including substrate-separating step; and

a thinning step in this order,

wherein in the strained semiconductor layer-including substrate-forming step,

a strained semiconductor layer-including substrate is formed bypreparing a graded layer, a buffer layer, and a strained semiconductor layer by epitaxial growth on a semiconductor substrate in this order from the semiconductor substrate side;

in the cleavage layer-forming step,

a cleavage layer is formed by implanting a cleavage substance containing at least one of hydrogen ion and rare gas ion into a region of at least one of the graded layer and the buffer layer of the strained semiconductor layer-including substrate;

in the bonding step,

the strained semiconductor layer-including substrate is bonded to the insulating substrate;

in the strained semiconductor layer-including substrate-separating step,

the strained semiconductor layer-including substrate is separated by cleavage of the cleavage layer by a heat treatment; and

in the thinning step,

at least the buffer layer of the strained semiconductor layer-including substrate bonded to the insulating substrate is removed by etching to give the single-crystal semiconductor thin film including the strained semiconductor layer.

According to this embodiment, a single-crystal semiconductor thin film excellent in surface flatness, or with a small surface roughness can be formed on the insulating substrate.

A single-crystal Si substrate is preferable as the above-mentioned semiconductor substrate. A SiGe mixed crystal layer is preferable as the graded layer and the buffer layer. A strained silicon layer is preferable as the strained semiconductor layer.

As mentioned above, this production method of the semiconductor device of the present invention excludes a high-temperature heat treatment step. Accordingly, even in use of a low heat-resistant insulating substrate, single-crystal semiconductor elements excellent in transistor characteristics can be provided.

Thus the present invention is also a semiconductor device including single-crystal semiconductor thin film-including single-crystal semiconductor elements on an insulating substrate,

wherein the insulating substrate has a heat-resistant temperature of 600° C. or lower (hereinafter, also referred to as a “first semiconductor device of the present invention”).

The configuration of the first semiconductor device of the present invention is not especially limited. The first semiconductor device may or may not include other components as long as it essentially includes the above-mentioned components.

In the present description, the heat-resistant temperature is intended to refer to a practical heat-resistant temperature in production of the semiconductor device or the single-crystal semiconductor thin film-including substrate. The heat-resistant temperature is preferably a practical heat-resistant temperature for deformation and/or accuracy of dimension, more preferably for deformation and accuracy of dimension. The heat-resistant temperature depends on processes and varies depending on magnification correction, alignment method, acceptable degree of alignment (design rule), etc., in photolithography. So the heat-resistant temperature is appropriately determined in accordance with desired process conditions. The practical heat-resistant temperature is empirically lower than a strain point about by 70° C. (acceptable) to 100° C. (practical). So it is preferably lower than the strain point by 70° C., and more preferably by 100° C.

The production method of the single-crystal semiconductor thin film-including substrate of the present invention also excludes a high-temperature heat treatment step. So curing of defects in the single-crystal semiconductor thin film, and suppression of thermal donor formation and activation of inactivated acceptor (preferably, boron) in the thin film are allowed even in use of a low heat-resistant insulating substrate.

Thus, the present invention is also a single-crystal semiconductor thin film-including substrate including a single-crystal semiconductor thin film on an insulating substrate,

wherein the insulating substrate has a heat-resistant temperature of 600° C. or lower.

The configuration of the single-crystal semiconductor thin film-including substrate of the present invention is not especially limited. The substrate may or may not include other components as long as it essentially includes the above-mentioned components.

The present invention is also a semiconductor device including single-crystal semiconductor elements produced using a single-crystal semiconductor thin film-including substrate produced by the production method of the single-crystal semiconductor thin film-including substrate of the present invention (hereinafter, also referred to as a “second semiconductor device of the present invention”).

The present invention is also a semiconductor device including single-crystal semiconductor elements produced using the single-crystal semiconductor thin film-including substrate of the present invention (hereinafter, also referred to as a “third semiconductor device of the present invention”).

The single-crystal semiconductor thin film-including substrate may be a SOI substrate.

The single-crystal semiconductor thin film-including single-crystal semiconductor element is preferably a single-crystal TFT.

As mentioned above, according to the present invention, the inactivated acceptors (preferably, boron) in the single-crystal semiconductor thin film can be activated. As a result, an activation ratio of the acceptors in the single-crystal semiconductor thin film can be increased to 50% or larger. The activation ratio of the single-crystal semiconductor thin film is preferably 10% (more preferably 25%, and still more preferably 50%) or larger.

It is preferable that the insulating substrate has a strain point of 800° C. (more preferably 670° C.) or lower. According to this, a glass substrate, which is used in a panel for display devices, can be used as the insulating substrate. The present invention can be preferably applied to thin-profile display devices such as an LCD device and an organic EL display device. The strain point is a temperature where internal stress in glass and the like is substantially removed in four hours, and it is a temperature giving a viscosity of 4×10¹⁴ P (dyn/cm²) to the glass and the like in four hours.

From the same view point, it is preferable that the insulating substrate is a glass substrate. Particularly preferably, the insulating substrate is a glass substrate having a strain point of 800° C. or lower and a heat-resistant temperature of 600° C. or lower.

Specific examples of preferable materials for the insulating substrate include (1) aluminoborosilicate glass, (2) aluminosilicate glass, (3) barium borosilicate glass, (4) glass mainly containing an oxide of aluminum (Al), boron (B), silicon (Si), calcium (Ca), magnesium (Mg), or barium (Ba).

The above-mentioned insulating substrate may be a metal substrate (preferably, stainless substrate) including an insulating layer (preferably, an inorganic insulating film such as a SiNₓ/SiO₂ multilayer film and a SiO₂ single film) formed thereon. The insulating substrate may be a resin substrate (plastic substrate), and an insulating layer (preferably, an inorganic insulating film such as a SiO₂ film) may be formed thereon. If the insulating substrate is a resin substrate, it is preferable that the single-crystal semiconductor elements are bonded to the insulating substrate with a resin adhesive, and it is also preferable that the single-crystal semiconductor thin film is bonded to the insulating substrate with a resin adhesive. The heat-resistant temperature of the resin substrate is preferably about 200° C. or lower.

According to the present invention, the transistor characteristics can be improved. More specifically, a subthreshold slope of the single-crystal semiconductor elements can be 75 mV/dec (preferably, 65 to 75 mV/dec) or smaller. The subthreshold slope of the single-crystal semiconductor elements is preferably 75 mV/dec (preferably 65 to 75 mV/dec) or smaller.

The semiconductor device may further include non-single-crystal semiconductor thin film-including non-single-crystal semiconductor elements on the insulating substrate. The single-crystal semiconductor thin film-including substrate may further include a non-single-crystal semiconductor thin film on the insulating substrate. According to this, the present invention can be preferably applied to thin-profile display devices such as a LCD device and an organic EL display device regardless of the size of the devices.

The non-single-crystal semiconductor thin film is preferably a polycrystal or amorphous semiconductor thin film.

The non-single-crystal semiconductor thin film-including non-single-crystal semiconductor element is preferably a non-single-crystal TFT.

It is preferable that a bonded interface between the insulating substrate and the single-crystal semiconductor elements contains SiO₂—SiO₂ bond or SiO₂-glass bond. It is also preferable that a bonded interface between the insulating substrate and the single-crystal semiconductor thin film contains SiO₂—SiO₂ bond or SiO₂-glass bond. According to this, the insulating substrate can be more tightly bonded to the single-crystal semiconductor elements or the single-crystal semiconductor thin film.

The single-crystal semiconductor thin film is preferably a single-crystal Si thin film. Specifically, the single-crystal semiconductor thin film preferably contains Si. The single-crystal semiconductor thin film may contain strained silicon. Thus, the single-crystal semiconductor thin film may have a tensile stress or a compressive stress, so the single-crystal semiconductor elements with an extremely high mobility can be provided.

It is preferable that the single-crystal semiconductor thin film is formed by epitaxial growth or floating zone. This can more suppress the thermal donor formation.

It is preferable that the single-crystal semiconductor thin film has an oxygen concentration of 10¹⁸/cm³ or lower. This also can more suppress the thermal donor formation.

The single-crystal semiconductor elements may include a PMOS transistor. The PMOS transistor may include a strained (100) silicon film and have a compressive stress. The PMOS transistor may include a strained (100) silicon film and have a tensile stress. The single-crystal semiconductor elements may include a NMOS transistor. The NMOS transistor may have a tensile stress. According to these embodiments, the PMOS and NMOS transistors with an extremely high mobility can be provided.

The single-crystal semiconductor thin film may contain at least one semiconductor selected from the group consisting of germanium (Ge), silicon carbide (SiC), and gallium nitride (GaN). Use of Ge enables the single-crystal semiconductor element to have a higher mobility, compared with use of silicon. Use of SiC enables the single-crystal semiconductor element to have higher mobility, higher photosensitivity, and higher resistance to junction voltage compared with use of silicon. Use of GaN can increase the resistance to junction voltage compared with use of silicon, and as a result, losses attributed to an LDD region and the like can be suppressed.

It is preferable that the insulating substrate is larger than a region where the single-crystal semiconductor elements are arranged. It is preferable that the insulating substrate is larger than the single-crystal semiconductor thin film. According to these embodiments, the present invention can be preferably applied to thin-profile display devices such as an LCD device, and an organic EL display device. Thus the insulating substrate may be larger than the single-crystal semiconductor thin film before being transferred. The insulating substrate is preferably larger than the semiconductor substrate (semiconductor wafer).

It is preferable that the semiconductor device includes a plurality of the regions, and the regions are closely arranged in an island pattern in a plane (more preferably in the entire plane) of the insulating substrate. It is preferable that the single-crystal semiconductor thin film-including substrate includes a plurality of the single-crystal semiconductor thin films, and the single-crystal semiconductor thin films are closely arranged in an island pattern in a plane (more preferably in the entire plane) of the insulating substrate. According to this, the entire insulating substrate can be covered with the single-crystal semiconductor elements or the single-crystal semiconductor thin films, which allows address transistors for pixels and the like to be constituted by high-performance transistors having uniform characteristics and including a single-crystal active layer. This also allows current driving display devices such as an organic EL display to provide high-quality images with suppressed display unevenness.

The semiconductor device may include a plurality of the regions where the single-crystal semiconductor elements are arranged, and the regions may be closely arranged in a tile pattern in a plane (more preferably in the entire plane) of the insulating substrate.

The single-crystal semiconductor thin film-including substrate may include a plurality of the single-crystal semiconductor thin films, and the thin films may be closely arranged in a tile pattern in a plane (more preferably in the entire plane) of the insulating substrate.

According to these embodiments, the plurality of arrangement regions or the plurality of the single-crystal semiconductor thin films are not necessarily evenly arranged in the insulating substrate plane (more preferably the entire plane). The thin films may be arranged with a space or without a space therebetween.

Thus, according to the semiconductor device, a plurality of the regions where the single-crystal semiconductor elements are arranged may be closely arranged in an island pattern in a plane (more preferably, the entire plane) of the insulating substrate. Further, according to the single-crystal semiconductor thin film-including substrate, the thin films may be closely arranged in an island pattern in a plane (more preferably, the entire plane) of the insulating substrate.

According to the semiconductor device, a plurality of the regions where the single-crystal semiconductor elements are arranged may be closely arranged in an island pattern in a plane (more preferably, the entire plane) of the insulating substrate in a tile pattern.

According to the single-crystal semiconductor thin film-including substrate, the single-crystal semiconductor thin films may be closely arranged in an island pattern in a plane (more preferably the entire plane) of the insulating substrate in a tile pattern.

Also according to these embodiments, the plurality of the regions of the single-crystal semiconductor elements or the plurality of the regions of the single-crystal semiconductor thin films may not be necessarily evenly arranged in the insulating substrate plane (more preferably the entire plane). The thin films may be arranged with a space or without a space therebetween.

It is preferable that a variation in thickness of the single-crystal semiconductor thin film is 10% (more preferably 5%) or smaller. As a result, the single-crystal semiconductor elements more excellent in transistor characteristics can be provided.

The single-crystal semiconductor thin film has an average surface roughness Ra of 5 nm (preferably 2 nm) or smaller. According to this, the single-crystal semiconductor elements more excellent in transistor characteristics can be provided.

As mentioned above, the present invention provides the thin film semiconductor elements (thin film elements) or the semiconductor thin films, each capable of increasing an acceptor activation ratio and providing excellent transistor characteristics, preferably produced by transfer performed in the below-mentioned manner, furnace annealing at 600° C. or lower for 1 hour or longer, and RTA at 650° C. or higher for 10 minutes or shorter. The transfer is carried out in the following manners in this order: cleavage substances such as hydrogen ions are implanted into a Si substrate or an element-on Si substrate at a predetermined depth; the substrate surface is flattened and then bonded to a larger insulating substrate; the hydrogen ion-implanted portion (cleavage zone) is cleaved to separate part of the Si substrate by a heat treatment; the entire surface of the transferred part undergoes etch-back or CMP until the thickness of the part is decreased to a predetermined value or until the semiconductor elements are divided.

The inventors also found the followings. In view of thermal donor formation and inactivation of acceptors, acceptors (preferably born) in a concentration higher than that needed for common devices, preferably about 5 to 20 times (more preferably on the order of 5 to 10 times) higher than that, are implanted in impurity doping processes for HALO formation, LDD formation, threshold control, and the like, and thereby, short channel effect or threshold voltage adjustment is allowed. According to the present invention, these are adopted in combination preferably, and thereby, sub-micron or deep sub-micron devices excellent in transistor characteristics such as short-channel characteristics and in controllability of threshold voltage are preferably formed on a low heat-resistant insulating substrate such as a glass substrate.

According to the present invention, preferably by subjecting the single-crystal semiconductor thin film (preferably, single-crystal Si thin film) with a low oxygen concentration prepared by FZ or epitaxial growth to furnace annealing at 600° C. or lower for example, thermal donor formation can be suppressed and the hydrogen concentration in the single-crystal semiconductor thin film can be decreased. Further, for example by performing RTA at a relatively-high temperature in a short time for the thin film after the annealing furnace, dislocations and the like in the silicon crystal can be efficiently cured. Thus, the semiconductor elements can show excellent TFT characteristics.

According to the present invention, preferably, a strained semiconductor layer (preferably strained Si layer) including a graded layer and a buffer layer (preferably, a SiGe mixed crystal layer) is transferred onto an insulating substrate, and further etching the graded layer and the buffer layer with an alkaline etchant, and thereby the strained semiconductor layer can be selectively removed. As a result, the single-crystal semiconductor thin film having uniform thickness and excellent surface flatness can be obtained. According to conventional technologies, it is difficult to decrease the thickness of a single-crystal semiconductor thin film on a large-size glass substrate on which elements or semiconductor thin films have been partially formed. In contrast, the above-mentioned method easily allows the decrease in thickness of such a film.

### EFFECT OF THE INVENTION

According to the semiconductor device, the single-crystal semiconductor thin film-including substrate, and production methods thereof of the present invention, transistor characteristics of single-crystal semiconductor thin film-including single-crystal semiconductor elements transferred onto a low heat-resistant insulating substrate can be improved.

### BEST MODES FOR CARRYING OUT THE INVENTION

The present invention is mentioned in more detail with reference to drawings showing Embodiments but not limited to only these Embodiments.

### Embodiment 1

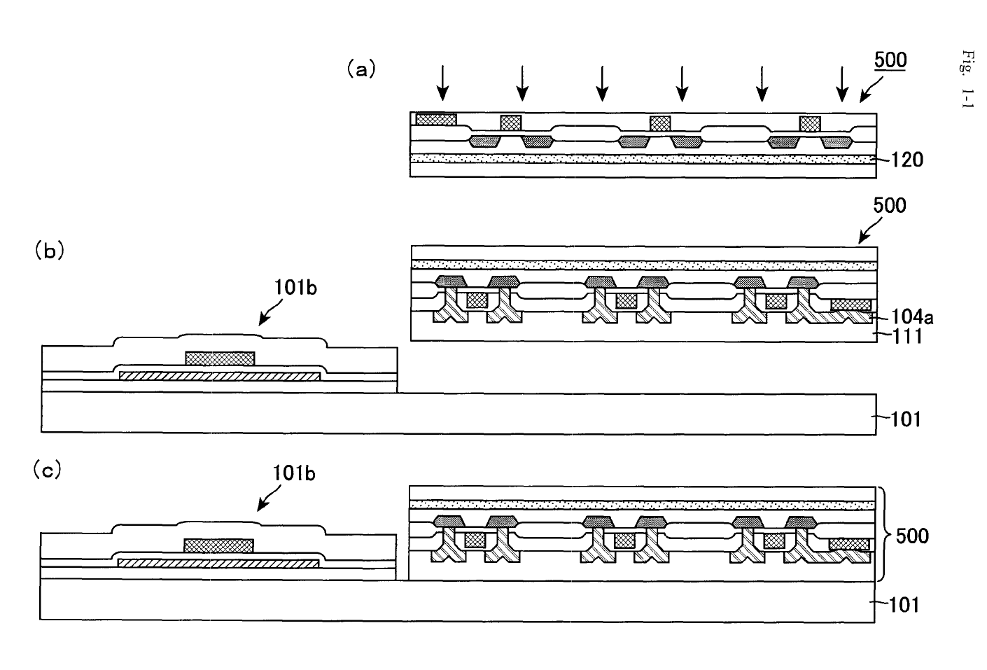

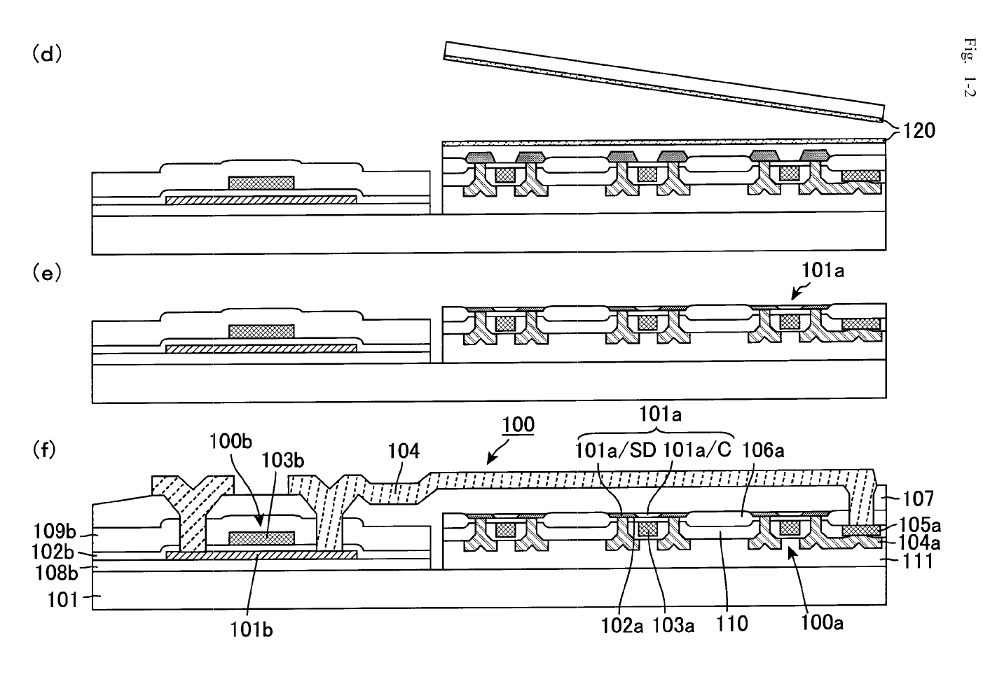

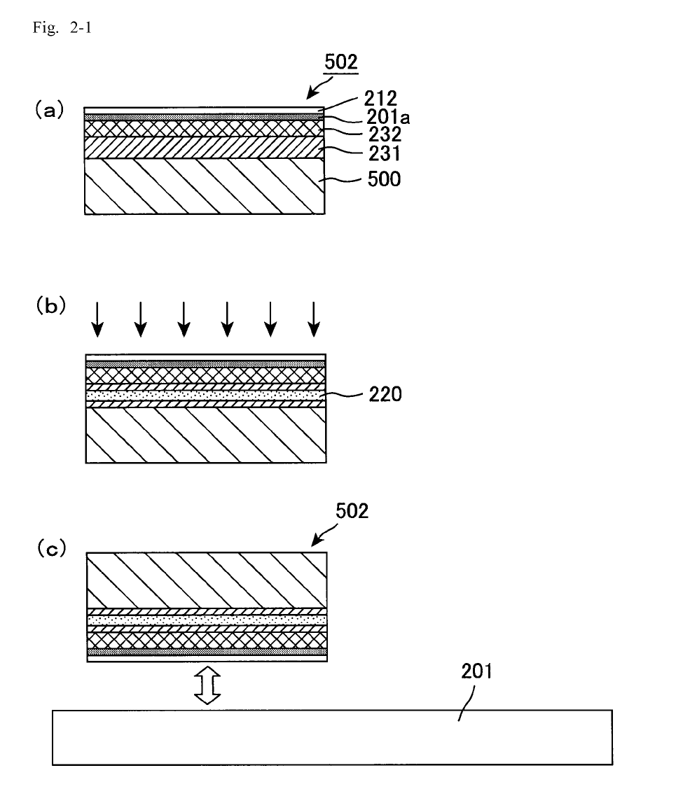

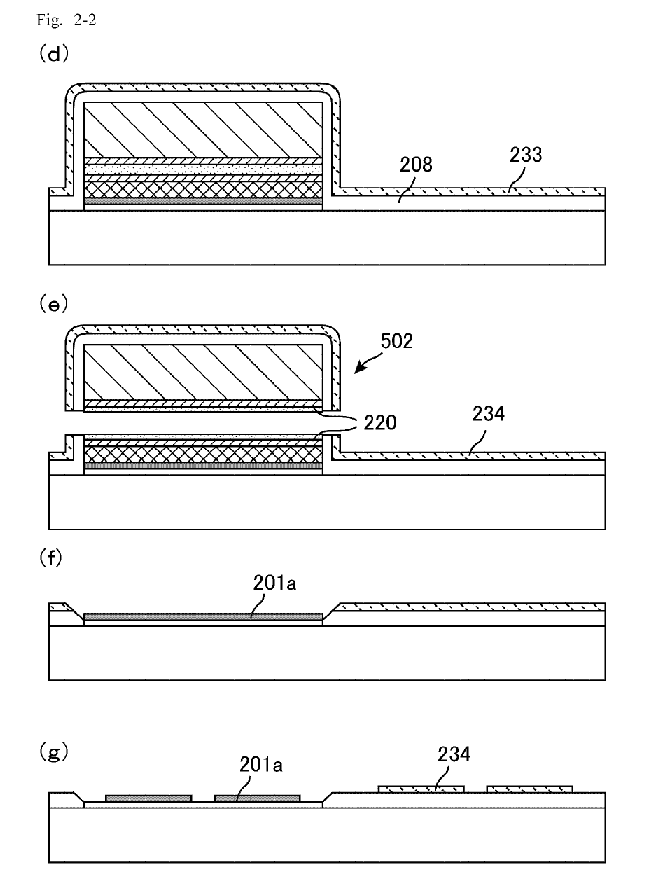

A single-crystal Si semiconductor device of Embodiment 1 and a production method thereof are mentioned below with reference to FIGS. 1-1 and 1-2. FIGS. 1-1(a) to 1-1(c) and FIGS. 1-2(d) to 1-2(f) are cross-sectional views each schematically showing a production step of the semiconductor device of Embodiment 1.

The semiconductor device of the present Embodiment includes at least MOS single-crystal Si TFTs disposed at part of a glass substrate used in active matrix display panels, larger than 6-inch, 8-inch, or 12-inch Si or quartz wafers, which are industrially used in LSI production, or disposed at part of a similar-sized insulating substrate, which has an insulating surface. According to a first application of the present invention, the semiconductor device is a high-performance and advanced semiconductor device that also includes non-single-crystal Si TFTs including amorphous silicon (a-Si) and/or polysilicon (Poly-Si) disposed at another region of the insulating substrate.

Referring to FIG. 1-2(f), a semiconductor device 100 of the present Embodiment includes, on an insulating substrate 101: MOS non-single-crystal Si TFTs 100b including a non-single-crystal Si thin film 101b made of polysilicon; MOS single-crystal Si TFTs (single-crystal Si thin film elements) 100a including a single-crystal Si thin film 101a; an interlayer flattening film 107 covering the TFTs 100a and 100b; and a metal wiring 104 connecting the TFTs 100a to 100b.

The insulating substrate 101 was a high strain-point glass, or Corning code 1737 glass (alkaline earth-aluminoborosilicate glass, strain point: 667° C., heat-resistant temperature: 560° C. to 600° C.) Heat-resistant temperatures are not uniquely determined, and depend on a process and vary depending on magnification correction, alignment method, acceptable degree of alignment (design rule), etc., in photolithography. For example, a Corning code 1737 glass (size: 730 nm×920 mm) in 3 micron line/space is commonly regarded to have a heat-resistant temperature (upper limit for several-hour heat treatment when the processes are taken into consideration) of 560° C. to 600° C. Practical heat-resistant temperatures for deformation are evaluated based on whether or not an object can be vacuum-held by a stage of an exposure device or based on a difference in pattern position before and after heat history, for example. It is preferable that the insulating substrate 101 has a heat-resistant temperature not lower than a heat treatment temperature (preferably 550° C. to 600° C.) in a step of forming the non-single-crystal Si thin film 101b.

A flat oxide film (not shown) composed of a SiO₂ (silicon dioxide) film with about 50 nm in thickness may be formed over the entire surface on the TFTs 100a and 100b side of the insulating substrate 101. In this case, the oxide film may function as a base layer.

The TFTs 100b include the non-single-crystal Si thin film 101b, agate insulating film 102b composed of a SiO₂ film, and a gate electrode 103b on abase coat insulating film 108b composed of a SiO₂/SiN multilayer film. Although the gate electrode 103b is made of TiN, it may be made of polysilicon, silicide, polycide, and the like. An interlayer insulating film 109b composed of a SiO₂ film with about 100 nm in thickness is formed to cover the TFTs 100b.

The TFTs 100a include: a gate electrode 103 self aligning with a channel 101a/C of the single-crystal Si thin film 101a; a contact 105a; flattening layers 110 and 111; a gate insulating film 102a composed of a SiO₂ film; the single-crystal Si thin film 101a having the channel 101a/C and a source-drain 101a/SD; and a metal wiring 104a connected to the source-drain 101a/SD and the contact 105a. Heavily-doped p-Si film was used as a material for the gate electrode 103a and the contact 105a. The contact 105a may be made of the single-crystal Si layer (the layer constituting the single-crystal Si thin film 101a). The TFTs 100a are divided from one another by a LOCOS oxide film 106a. The film 106a may be STI (shallow trench isolation).

These single-crystal Si TFTs 100a are transferred onto the insulating substrate 101 after the following processes. A semiconductor portion of the TFTs 100a is first formed on a single-crystal Si substrate; hydrogen ions at a predetermined concentration are implanted into the Si substrate at a predetermined depth; and then the Si substrate including the gate electrode 103a, the gate insulating film 102a, and the single-crystal Si thin film 101a is bonded to the insulating substrate 101. A heat treatment for this single-crystal Si substrate causes fine bubbles formed in the hydrogen ion-implanted portion (cleavage layer). Then, this cleavage layer is cleaved to separate the Si substrate from the insulating substrate 101. As a result, transfer of the TFTs 100a onto the insulating substrate 101 is completed.

The formation of the gate electrode 103a, the contact 105a, the metal wiring 104a and the like of the TFTs 100a, and the impurity ion implantation into the source-drain 101a/SD and the like may be performed after the transfer. However, by performing these processes before the transfer, the single-crystal Si thin film can be finely processed more easily as compared with the case where these processes are performed after the transfer.

Particularly, if the insulating substrate 101 is a glass substrate, a high-temperature heat treatment is not performed for the insulating substrate 101 after the transfer because the glass substrate has a low heat resistant temperature. So the hydrogen that has been used for the cleavage separation of the single-crystal Si substrate is difficult to sufficiently remove. Accordingly, it is difficult to completely eliminate localized energy level, dislocation, and the like, formed in process of the production, and further, thermal donor formation, inactivation of boron, and the like, are caused, which has adverse effects on the device characteristics. The thermal donor formation and the inactivation of acceptors such as boron are in accordance with a concentration profile of the impurities doped into the single-crystal Si substrate. It is substantially impossible to compensate the adverse effects by performing impurity ion implantation (or ion doping) after the transfer due to constraints of gate electrode position (upper or lower position) or accuracy of photolithography. The present inventors studied in detail about the data on the thermal donor formation, the boron inactivation, and the like, and about heat treatment conditions closely related to them. The inventors found that optimum transistor characteristics can be obtained, for example, when furnace annealing at lower than 650° C. for hydrogen removal, transient annealing at 650° C. or higher for a short time are performed, and further, a boron amount implanted for threshold control, a HALO formation, an LDD formation, a source-drain formation, and the like before the hydrogen ion implantation, is increased, and further, the implanted amount of phosphor or As is decreased. These findings are applied to the present Embodiment.

According to the semiconductor device 100 of the present invention, as mentioned above, the MOS non-single-crystal Si TFTs 100b and the MOS single-crystal Si TFTs 100a are both arranged on one insulating substrate 101. The semiconductor device 100 can be a high performance and advanced semiconductor device where circuits different in characteristics are integrated.

Further, the production costs on the semiconductor device 100 can be lower than costs on production of a semiconductor device including only single-crystal Si TFTs on one insulating substrate 101.

These production steps have no such area constrains as arising when only single-crystal Si TFTs are disposed. Displays larger than large-size Si wafers can be produced without any substrate size constraints.

If, for example, the semiconductor device 100 is applied to an active matrix substrate used in an LCD device, the device 100 further includes a SiNₓ (silicon nitride) film, a resin flattening film, a via hole, a transparent electrode, and the like, for LC display. The non-single-crystal Si TFTs (non-single-crystal Si elements) 100b constitute TFTs in a driver portion and a display portion. The single-crystal Si device TFTs 100a, which can be used in device needing higher performances, constitute a timing controller, a memory, and the like. The driver portion may be also constituted by the TFTs 100a, which is determined by considering the costs and the performances. The function and application of the TFTs 100a and 100b are determined depending on their characteristics. As a result, high performance and advanced semiconductor device and display device can be provided.

In the semiconductor device 100, an integrated circuit is formed in the non-single-crystal Si thin film 101b region and in the single-crystal Si thin film 101a region. This allows integrated circuits including a pixel array to be formed in different regions in accordance with desired configuration and characteristics. Further, the integrated circuits formed in different regions can be different in performances, operation speed, power voltage, and the like. For example, the circuits may be so designed to be different in at least one of gate length, gate insulating film thickness, power source voltage, and logic level from one region to the other.

Thus, a semiconductor device or a display device that can show more various functions attributed to the elements having different characteristics from one region to the other can be provided.

In the semiconductor device 100, the IC is formed in both of the non-single-crystal Si thin film 101b region and the single-crystal thin film 101a region. The ICs can be formed with process rules in accordance with the respective regions. For example, in short channel length elements, no crystal grain boundary exists in the single-crystal Si thin film 101a region and so a variation in TFT characteristics is not so increased. In contrast, in the non-single-crystal thin film 101b region, the variation in the TFT characteristics is highly increased under the influence of the grain boundary. Thus, it is necessary to determine the process rule in accordance with the respective regions, i.e., the thin film 101a region and the thin film 101b region. According to the semiconductor device 100, the ICs with process rules suitable for their arrangement regions can be formed.

The size of the single-crystal Si device formed on the semiconductor device 100 is determined by a wafer size of an LSI production apparatus. A wafer size of a common LSI production apparatus is enough for a high-speed DAC (current buffer), which needs a high-speed performance, a power consumption, a high-speed logic, a timing generator, a variation, etc., or for a circuit such as a processor, each of which needs to include the thin film 101a.

The production method of the semiconductor device 100 is mentioned with reference to FIGS. 1-1 and 1-2 below.

The production method of the device 100 is roughly mentioned below. A single-crystal Si substrate 500 including a portion that can give the single crystal Si TFTs 100a after thinning is prepared, and hydrogen ions at a predetermined concentration are previously implanted into the substrate 500 at a predetermined depth. This substrate 500 is bonded to the insulating substrate 101 with an insulating surface. Then, the substrate 500 is cleaved by cleavage of the hydrogen ion-implanted portion (cleavage layer) by a heat treatment. Then, the substrate 500 is thinned by etching or polishing to give the single crystal Si thin film 101a, and the elements are divided. Further, the interlayer insulating film 107 including a SiO₂ film and the like is formed by deposition to flatten a surface defined by the TFTs 100a.

Specifically, some of CMOS processes are previously performed in a common IC production line. Specifically, performed are implantation of impurity ions (e.g., boron and phosphorus) for the channel 101a/C formation (threshold voltage control), formation of the gate insulating film 102a and the LOCOS oxide film 106a, pattern formation of the gate electrode 103a and the contact 105a, implantation of impurity ions (e.g., boron, phosphorus, and arsenic) for LDD formation, implantation of impurity ions (e.g., boron, and phosphorus) for HALO formation (oblique ion implantation for suppression of short channel effect), and implantation of impurity ions (e.g., BF₂⁺ and As⁺) for source-drain 101a/SD formation (element-forming step and doping step). Actually, in the present Embodiment, born and phosphorus were used as the implanted ions for the channel 101a/C formation; BF₂⁺ and As⁺ for the LDD formation; boron and phosphorus for the HALO formation; and BF₂⁺ and As⁺ for the source-drain 101a/SD formation.

With respect to the impurity ion implantations for the source-drain 101a/SD formation, for the channel 101a/C formation (threshold voltage control), for the LDD formation, and for the HALO formation (oblique ion implantation for suppression of short channel effect), each of boron and BF₂⁺ in an amount about 5 to 10 times larger than an amount optimum for a finally completed element was implanted, and phosphorus was implanted so that its concentration after the implantation is reduced by about 2 to 5×10¹⁶ cm⁻³. The adjustment for each amount is preferably in accordance with the below-mentioned heat treatment conditions, a Si thickness, desired TFT characteristics.

Then, an activation treatment (activation step) was performed under predetermined conditions, and a SiO₂ film was formed and then flattened by CMP (chemical-mechanical polishing) to give the flattening film 110 (flattening step). A protective insulating film composed of a SiO₂ film may be formed before forming the flattening film 110. In the present Embodiment, the flattening film 110 functions as a protective insulating film.

As shown in FIG. 1-1(a), the cleavage substances, or hydrogen ions at 6×10¹⁶/cm² were implanted at a predetermined energy, and thereby a hydrogen ion-implanted portion (cleavage layer) 120 was formed in the single-crystal Si substrate 500 (cleavage layer-forming step).

Instead of the substrate 500, a single-crystal Ge substrate may be used as the single-crystal semiconductor substrate. Specifically, a single-crystal Ge thin film may be used instead of the single-crystal Si thin film 101a.

Referring to FIG. 1-1 (b), formation of contact holes, metal layer deposition, and patterning are successively formed to give the metal wiring 104a. The metal wiring 104a was a multi-layer body composed of tungsten (W) and titanium nitride (TiN) barrier layer.

A SiO₂ film is further deposited to cover the metal wiring 104a in the single crystal Si substrate 500 using a gaseous mixture of TEOS and O₂ by PECVD. Then, this SiO₂ film is flattened to give the flattening film 111. Dummy pattern and CMP were employed if necessary in the flattening treatment.

The single-crystal Si substrate 500 including the TFTs 100a was divided into predetermined sizes, and as shown in FIG. 1-1 (c), a high-strain point glass (e.g., the above-mentioned glass substrate), which is industrially used for TFT-LCDs, was used as an insulating substrate (final substrate) 101 having an insulating surface. Both of the substrate 500 and the non-single-crystal Si TFTs 100b-including insulating substrate 101 were activated (hydrophilized) by being washed with a SC-1 solution. Then, the substrate 500 was positioned with a predetermined region of the insulating substrate 101 and then tightly bonded to each other at room temperatures (bonding step). More specifically, the flattening film 111 of the substrate 500 was bonded to the insulating substrate 101. When a glass substrate is used, its surface can be hydrophilized without depositing the SiO₂ film thereon. Some kinds of glasses satisfy an average surface roughness Ra of 0.2 to 0.3 nm or smaller, desired for excellent bonding property.

The substrates 500 and 101 are bonded by Van der Waals forces and hydrogen bonding. A heat treatment at 200° C. to 300° C. for about four hours causes a reaction of —Si—OH+—Si—OH→Si—O—Si+H₂O, and thereby the bond between the two substrates changes into a tight bond between the atoms.

The single-crystal Si TFTs 100a are bonded to the insulating substrate 101 with the flattening film 111, which is an inorganic insulating film. Compared with use of a conventional adhesive, pollution of the single-crystal Si thin film 101a can be surely prevented.

Thus, it is preferable that the TFTs 100a and the insulating substrate 101 are finally bonded to each other through SiO₂—SiO₂ bond (SiO₂ film and SiO₂ film bond) or SiO₂-glass bond (SiO₂ film and glass bond).

The insulating substrate 101 may be a metal substrate (for example, a stainless substrate) having a flattened surface defined by a SiNₓ—SiO₂ multilayer film, a SiO₂ single film, and the like formed thereon. As a result, the heat resistance and shock resistance of the insulating substrate 101 can be improved. This embodiment is particularly preferably applied to organic EL displays because the insulating substrate 101 may not have transparency when being used in organic EL displays.

The insulating substrate 101 may be a plastic substrate having a flat surface defined by a SiO₂ film formed thereon. Further, when a plastic substrate is used as the insulating substrate 101, the TFTs 100a and the insulating substrate 101 may be bonded with an adhesive, although the pollution of the thin film 101a is still concerned.

In the present description, the average surface roughness Ra is an arithmetic mean height (Ra) and measured with an atomic force microscopy (AMF) in accordance with JIS B 0601. For example, the substrate surface in 5 μm×5 μm is measured.

Then, the insulating substrate 101 on which the TFTs 100a have been bonded was heated at about 550° C. by RTA (rapid thermal annealing). Thus, as shown in FIG. 1-2 (d), part of the substrate 500 was separated along the hydrogen ion-implanted portion 120 (semiconductor substrate-separating step).

Now referring to FIG. 1-2 (e), the portion 120-side surface of the substrate 500 was thinned by polishing and/or etching to give the single-crystal Si thin film 101a. Thus, the element division had been completed (element-dividing step).

A furnace heat treatment (a first heat treatment step) at 560° C. to 650° C. for 1 to 5 hours and RTA (a second heat treatment step) at 650° C. or higher for 11 minutes or shorter are performed. Actually, in the present Embodiment, the first heat treatment step was performed at 600° C. for 4 hours and the second heat treatment step was performed at 675° C. for 10 minutes. In the first heat treatment step, the hydrogen concentration in Si is reduced, and the defects slightly generated by the hydrogen ion implantation are cured in the second heat treatment step. Thus, the hydrogen atoms can be sufficiently removed from Si, and thermal donor and lattice defects in Si and the like, can be completely eliminated. Further, the acceptors can be reactivated. As a result, reproducibility of the transistor characteristics can be improved, and the transistor characteristics can be stabilized. The activation ratio of the acceptors in the thin film 101a is 10% (more preferably 25%, and still more preferably 50%) or larger. In the present Embodiment, the activation ratio can be about 80%.

The time of the RTA (the second heat treatment step) depends on the heat resistance of the insulating substrate 101 (the glass substrate in the present Embodiment), and it is adjusted within a range where deformation of the insulating substrate 101 is allowed. Specifically, the RTA time needs to become shorter as the treatment temperature is increased. From viewpoint of expansion and contraction or warpage of the substrate 101, the RTA time is preferably as short as possible. The RTA time is commonly determined within a range where no influences are imposed on the insulating substrate 101. In order to improve the device characteristics, it is preferable that the RTA time is as long as possible. The low limit of the time is determined depending on desired device characteristics. When the RTA temperature is 675° C., a reduction in the RTA time by 3 minutes is usually enough to make temperature control difficult, and a variation in device characteristics is increased, although this depends on performances of an apparatus used for the RTA.

The RTA temperature is appropriately determined in accordance with the implanted hydrogen amount and the like. When it is too high, a profile of the impurity (especially boron) is changed. So preferably, the RTA temperature is preferably as low as possible within a range where the impurity profile is not changed, for example, at 850° C. (preferably, 820° C.) or lower. In order to reactivate the acceptors, it is preferable that the RTA temperature is as high as possible and is not lower than 650° C.

The activation ratio is estimated from a ratio of a density of active acceptors estimated based on a threshold voltage of a transistor to the total number of atoms or density of acceptors (borons in the present Embodiment) evaluated by SIMS (secondary ion mass spectrometer).

Referring to FIG. 1-2(f), the interlayer flattening film 107 composed of a SiO₂ film is deposited over the entire substrate surface to have a thickness of about 300 nm by a gaseous mixture of SiH₄ and N₂O or a gaseous mixture of TEOS and O₂ by plasma CVD.

Then, formation of contact holes, deposition of a barrier metal (e.g., TiN/Ti) and an Al—Si layer, and patterning were successively performed. As a result, the metal wiring 104 containing an Al—Si alloy was formed in the contact holes and on the interlayer flattening film 107.

According to the production method of the semiconductor device 100 of the present Embodiment, the non-single-crystal Si thin film (p-Si thin film) 101b is formed, and then, the single-crystal Si TFTs 100a are formed. Specifically, the TFTs 100a are bonded to the insulating substrate 101 on which the thin film 101b has been formed. So the surface of the insulating substrate 101, to which an intermediate substrate 600 is bonded, preferably has flatness. A protective film (for example, a molybdenum (Mo) film) is formed on the substrate 101 surface, and the oxide film in the bonding region is removed by fluoric acid etc., and then, the protective film is removed by a commercially-available SLA etchant and the like. In this manner, bonding failure and the like can be prevented.

According to the present Embodiment, the single-crystal Si thin film 101a on the insulating substrate 101 is subjected to the low-temperature and long-time heat treatment and the high-temperature and short-time heat treatment. So in the thin film 101a, the defects can be cured, the thermal donors can be reduced, and further, the inactivated borons can be activated. As a result, the characteristics of the TFTs 100a can be improved.

### Embodiment 2

A thin film semiconductor device including a single-crystal strained Si of Embodiment 2 and a production method thereof are mentioned with reference to FIGS. 2-1 to 2-3 below. FIGS. 2-1(a) to 2-1(c), FIGS. 2-2(d) to 2-2(g), and FIGS. 2-3(h) to 2-3(l) are cross-sectional views each schematically showing a production step of the semiconductor device of Embodiment 2.

With reference to FIG. 2-1(a), a strained Si structure is mentioned first. A mixed crystal of GeₓSi₁₋ₓ graded material is epitaxially grown (epi-growth) on a Si wafer (single-crystal Si substrate) 500 to form a graded layer (SiGe layer) 231 with about 1 μm in thickness, and thereon, a GeₓSi₁₋ₓ (SiGe mixed crystal layer) is grown to have a thickness of about 1 μm as a buffer layer (buffer GeSi layer) 232. As a result, dislocation-free GeₓSi₁₋ₓ is grown. Further, thereon a Si layer with a thickness of about 10 to 20 nm is epitaxially grown, thereby growing a stained Si layer 201a, which is a single-crystal strained Si thin film having a tensile stress due to a difference in lattice constant. Thereon a SiO₂ film 212 with a thickness of about 50 to 100 nm is grown by LPCVD and the like, and if necessarily, a SiO₂ film, which finally has a thickness equivalent to that of the SiO₂ film 212, is formed.

Thus, the strained Si substrate 502 having a tensile or compressive stress is formed. Thus an NMOS transistor having a (100) face having a tensile stress shows a mobility about two times higher than that of an NMOS transistor including single-crystal Si at x=about 0.3. Similarly, a PMOS transistor having a (110) face having a tensile stress or a PMOS transistor having a (100) face having a compressive stress shows a mobility about two times higher than that of a PMOS transistor including single-crystal Si.

Instead of the strained Si substrate 502 including the strained Si layer 201a formed by epitaxial growth, a substrate including epitaxially grown SiC or GaN may be used.

As shown in FIG. 2-1(b), cleavage substances, or hydrogen ions are implanted so that the peak of the hydrogen ions is positioned in a predetermined region (the graded layer 231 in the present Embodiment) of the graded layer 231 and the buffer layer 232, whereby the hydrogen ion-implanted portion (cleavage layer) 220 is formed (cleavage layer-forming step). The cleavage substances may be rare gas ion, in addition to H ion and H₂ ion. Further, H₂ ion may be used in combination with rare gas ion.

The strained Si substrate 502 is separate into predetermined sizes, and as shown in FIG. 2-1(c), a high-strain point glass (e.g., a glass substrate in Embodiment 1), which is industrially used for TFT-LCDs, is used as an insulating substrate (final substrate) 201 having an insulating surface. Both of the strained Si substrate 502 and the insulating substrate 201 are activated (hydrophilized) bybeing impregnated in a solution containing hydrogen peroxide such as a SC-1 solution. Then, the substrate 502 is positioned with a predetermined region of the insulating substrate 201 and then tightly bonded to each other at room temperatures (bonding step). More specifically, the SiO₂ film 212 of the strained Si substrate 502 is bonded to the insulating substrate 201. When a glass substrate is used, its surface can be hydrophilized without depositing the SiO₂ film thereon. Some kinds of glasses satisfy an average surface roughness Ra of 0.2 to 0.3 nm or smaller, desired for excellent bonding property.

The strained Si substrate 502 and the insulating substrate 201 are bonded by Van der Waals forces and hydrogen bonding. The bonding strength is increased by a heat treatment at 200° C. to 300° C. for about two hours, and then, as shown in FIG. 2-2(d), an interlayer insulating film 208 composed of a SiO₂ film and an a-Si film 233 are successively deposited by PECVD. The a-Si film 233 undergoes dehydrogenation annealing at 550° C. to reduce the hydrogen atoms contained therein. Then the a-Si film 233 (except for the strained Si layer 201a) is irradiated with XeCl eximer laser and the like to be crystallized, and as a result, a Poly-Si film 234 is formed. The dehydrogenation annealing at about 550° C. causes a reaction of —Si—OH+—Si—OH→Si—O—Si+H₂O, and thereby the bond between the two substrates changes into a tight bond between the atoms. This annealing also causes fine bubbles formed in the hydrogen ion-implanted portion 120. Then, this portion 220 is cleaved to separate part of the substrate 502 from the substrate 201 (semiconductor substrate-separating step).

Thus, it is preferable that the strained Si layer 201a and the insulating substrate 201 are finally bonded to each other through SiO₂—SiO₂ bond (SiO₂ film and SiO₂ film bond) or SiO₂-glass bond (SiO₂ film and glass bond).

The insulating substrate 201 may be a metal substrate (for example, a stainless substrate) having a flattened surface defined by a SiNₓ—SiO₂ multilayer film, a SiO₂ single film, and the like formed thereon. As a result, the heat resistance and shock resistance of the insulating substrate 201 can be improved. This embodiment is preferably applied to organic EL displays because the insulating substrate 201 may not have transparency when being used in organic EL displays.

The insulating substrate 201 may be a plastic substrate having a flat surface defined by a SiO₂ film formed thereon. Further, when a plastic substrate is used as the insulating substrate 201, the TFTs 200a (the strained Si substrate 502) and the insulating substrate 201 may be bonded with an adhesive, although the pollution of the strained Si layer 201a is still concerned.

At the time of the ELA (excimer laser annealing), the bulk Si is separated and so it is necessary to prevent the strained Si layer 201a from being irradiated with the layer. However, this does not need to be considered in the present Embodiment, for example, when a strained Si thin film (the strained Si layer 201a) is formed in a tile (island) pattern on a glass substrate (the insulating substrate 201).

Now referring to FIG. 2-2 (f), the graded layer 231 and the buffer layer 232 on the strained Si layer 201a are removed by etching with an alkaline solution such as TMAH. As a result, the insulating substrate 201 including the strained Si layer 201a, which is a single-crystal strained Si thin film (single-crystal semiconductor thin film), formed thereon, is provided (thinning step).

The graded layer 231 and the buffer layer 232 are easy to be etched with an alkaline solution compared with the strained Si layer 201a. Specifically, a difference in etching rate between the strained Si layer 201, and the graded layer 231 and the buffer layer 232 can be large. As a result, a SOI substrate including the strained Si layer 201a so excellent in flatness can be produced.

The thus-produced SOI substrate has a surface defined by a surface (surface on the side opposite to the buffer layers 231 and 232) more excellent in flatness of the strained Si layer 201a. More specifically, the average surface roughness Ra of the strained Si layer 201a can be 5 nm or smaller.

The variation in thickness of the strained Si layer 201a can be 10% or smaller (more preferably, 5%).

Then a furnace heat treatment (a first heat treatment step) at 560° C. to 650° C. for 1 to 5 hours (preferably 4 hours or shorter) and RTA (a second heat treatment step) at 650° C. or higher (preferably 675° C.) for 11 minutes or shorter (preferably 10 minutes) are performed. In the first heat treatment step, the hydrogen concentration in Si is reduced, and the defects slightly generated by the hydrogen ion implantation are cured in the second heat treatment step. Thus, the hydrogen atoms can be sufficiently removed from Si, and thermal donor and lattice defects in Si can be completely eliminated. Further, the acceptors can be reactivated. As a result, reproducibility of the transistor characteristics can be improved and the transistor characteristics can be stabilized. The activation ratio of the acceptors in the strained Si layer 201a can be 10% (more preferably 25%, and still more preferably 50%) or larger.

The time of the RTA (the second heat treatment step) depends on the heat resistance of the insulating substrate 201 (the glass substrate in the present Embodiment), and it is adjusted within a range where deformation of the insulating substrate 201 is allowed. Specifically, the RTA time needs to become shorter as the treatment temperature is increased. From viewpoint of expansion and contraction or warpage of the substrate 201, the RTA time is preferably as short as possible. The RTA time is commonly determined within a range where no influences are imposed on the insulating substrate 201. In order to improve the device characteristics, it is preferable that the RTA time is as long as possible. The low limit of the time is determined depending on desired device characteristics. When the RTA temperature is 675° C., a reduction in the RTA time by 3 minutes is usually enough to make temperature control difficult, and a variation in device characteristics is increased, although this depends on performances of an apparatus used for the RTA.

The RTA temperature is appropriately determined in accordance with the implanted hydrogen amount, the material for the intermediate substrate, and the like. When it is too high, the strained Si layer 201a is relaxed, leading to a reduction in the effects of the strained Si layer or a change of impurity (especially boron) profile. So preferably, the RTA temperature is as low as possible within a range where the strained Si layer 201a is not relaxed or the impurity profile is not changed, for example, at 850° C. (preferably, 820° C.) or lower. In order to reactivate the acceptors, it is preferable that the RTA temperature is as high as possible and is not lower than 650° C.

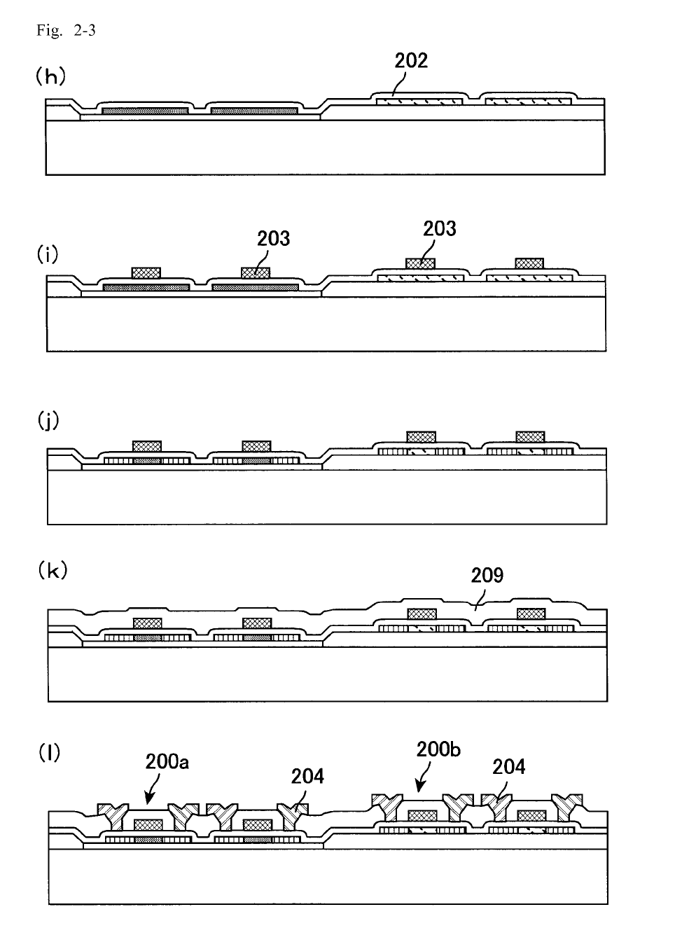

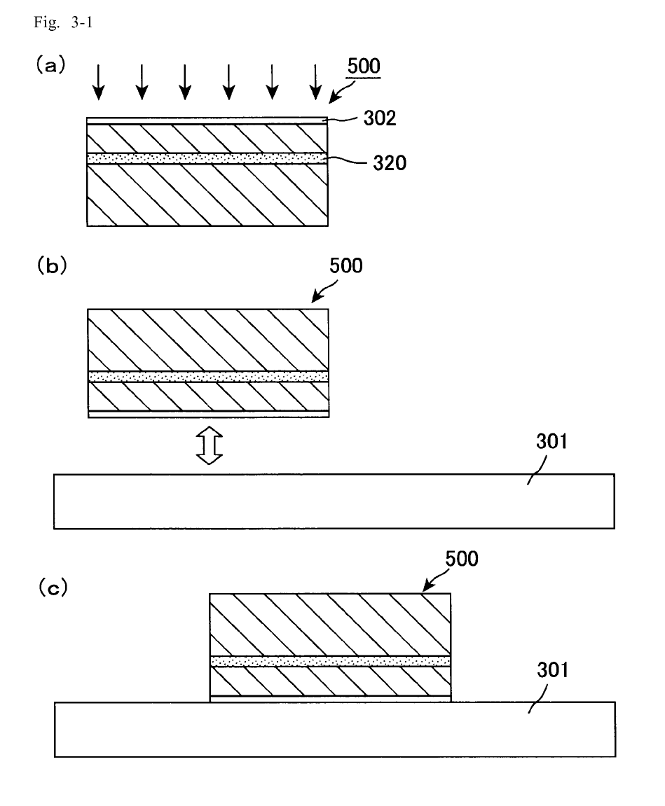

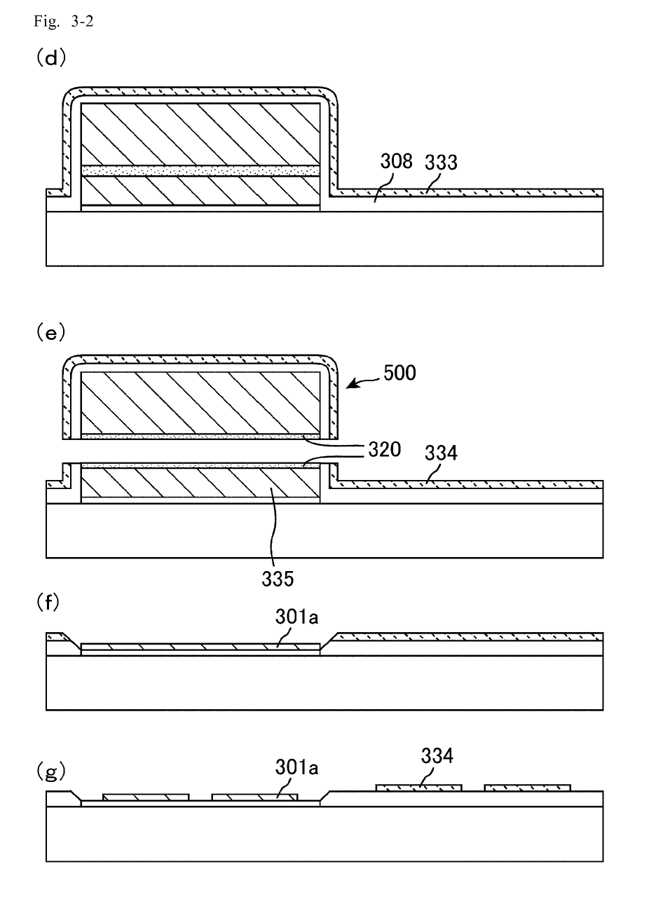

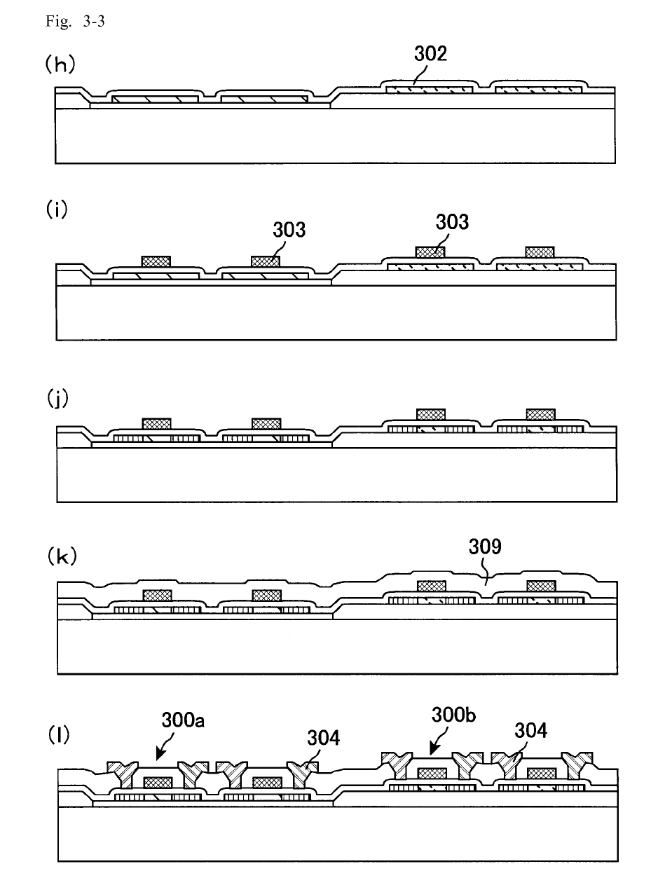

Referring to FIG. 2-2 (g), the Poly-Si film 234 and the strained Si layer 201a are formed into an island pattern by etching. Then, as shown in FIG. 2-3 (h), a gate insulating film (gate oxide film) 202 composed of a SiO₂ film with a thickness of about 50 nm is deposited on the entire substrate surface by plasma CVD using a gaseous mixture of SiH₄ and N₂O or a gaseous mixture of TEOS and O₂. Then, a gate electrode 203 is pattern-formed as shown in FIG. 2-3 (i).

Then, the impurity ion-implanting step (involving ion implantation of phosphorus and boron, in FIG. 2-3 (j)), and the impurity ion-activating step are performed. The activation annealing in this activation step may be performed as the short time annealing (for example, RTA at 650° C. or higher for 10 minutes or shorter) in the second heat treatment step. Specifically, after the first heat treatment step, the patterning step for the Poly-Si film 234 and the strained Si layer 201a, the gate insulating film 202-forming step, and the gate electrode 203-forming step, are performed, and then, the second heat treatment step may be performed.

As shown in FIG. 2-3 (k), a SiN film is formed by plasma CVD using a SiH₄ and N₂O gaseous mixture, and a SiO₂ film is formed by plasma CVD using a TEOS and O₂ gaseous mixture. Thus, an interlayer insulating film 209 composed of a SiN film-SiO₂ film multilayer body is formed.

After formation of contact holes, and a metal wiring 204 (FIG. 2-3(l)), the single-crystal Si TFTs 200a including the strained Si layer 201a and the non-single-crystal Si TFTs 200b including the Poly-Si film 234 can be formed.

According to the present Embodiment, the single-crystal Si thin film 201a on the insulating substrate 201 is subjected to the low-temperature and long-time heat treatment and the high-temperature and short-time heat treatment. So the defects in the strained Si layer 201a can be cured and the thermal donor in Si can be reduced. Further, the inactivated boron can be activated. As a result, the characteristics of the TFTs 200a including the strained Si layer 201a can be improved.

The graded layer 231 and the buffer layer 232, which are easy to be etched, are selectively etched, and thereby only the strained Si layer 201a can effectively remain on the substrate 201. As a result, the strained Si layer 201a with excellent flat surface can be formed on the insulating substrate 201. Accordingly, the characteristics of the single-crystal Si TFTs 200a including the strained Si layer 201a can be more improved.

The strained Si layer 201a may have the element structure or part thereof before being bonded to the intermediate substrate 600. In this case, the element structure or part thereof is formed in the layer 201a as mentioned in Embodiment 1.

### Embodiment 3

A thin film semiconductor device including single-crystal Si of Embodiment 3 and a production method thereof are mentioned with reference to FIGS. 3-1 and 3-3 below. FIGS. 3-1(a) to 3-1(c), FIGS. 3-2(d) to 3-2(g), and FIGS. 3-3(h) to 3-3(l) are cross-sectional views schematically showing a production step of the semiconductor device of Embodiment 3.

A thermal oxide film 302, for example, with a thickness of 50 nm is formed on a Si wafer (single-crystal Si substrate) 500, first.

As shown in FIG. 3-1 (a), cleavage substances, or hydrogen ions are implanted into the single-crystal Si layer so that the peak of the hydrogen ions is positioned at a predetermined depth, whereby a hydrogen ion-implanted portion (cleavage layer) 320 is formed (cleavage layer-forming step). The cleavage substances may be rare gas ion, in addition to H ion and H₂ ion. Further, H₂ ion may be used in combination with rare gas ion.

The single-crystal Si substrate 500 is separate into predetermined sizes, and as shown in FIGS. 3-1 (b) and 3-1 (c), a high-strain point glass (e.g., a glass substrate used in Embodiment 1), which is industrially used for TFT-LCDs, is used as an insulating substrate (final substrate) 301 having an insulating surface. Both of the substrates 500 and 301 are activated (hydrophilized) by being impregnated in a solution containing hydrogen peroxide such as a SC-1 solution. Then, the substrate 500 is positioned with a predetermined region of the insulating substrate 301 and then tightly bonded to each other at room temperatures (bonding step). More specifically, the thermal oxide film 302 of the single-crystal Si substrate 500 is bonded to the insulating substrate 301. When a glass substrate is used, its surface can be hydrophilized without depositing the SiO₂ film thereon. Some kinds of glasses satisfy an average surface roughness Ra of 0.2 nm to 0.3 nm or smaller, desired for excellent bonding property.

The single-crystal Si substrate 500 and the insulating substrate 301 are bonded by Van der Waals forces and hydrogen bonding. The bonding strength is increased by a heat treatment at 200° C. to 300° C. for about two hours, and then, as shown in FIG. 3-2 (d), an interlayer insulating film 308 composed of a SiO₂ film and an a-Si film 333 are successively deposited by PECVD. The a-Si film 333 undergoes dehydrogenation annealing at 550° C. to reduce the hydrogen atoms contained therein and then is irradiated with XeCl eximer laser and the like to be crystallized, and as a result, a Poly-Si film 334 is formed. The dehydrogenation annealing at about 550° C. causes a reaction of —Si—OH+—Si—OH→Si—O—Si+H₂O, and thereby the bond between the two substrates changes into a tight bond between the atoms. This annealing also causes fine bubbles formed in the hydrogen ion-implanted portion 320. Then, as shown in FIG. 3-2 (e), this portion 320 is cleaved to separate part of the substrate 500 from the substrate 301 and the single-crystal Si layer 355 can be left on the insulating substrate 301 (semiconductor substrate-separating step).

Thus, it is preferable that the single-crystal Si thin film 301a (the thinned single-crystal Si layer 335) and the insulating substrate 301 are finally bonded to each other through SiO₂—SiO₂ bond (SiO₂ film-SiO₂ film bond) or SiO₂-glass bond (SiO₂ film-glass bond).

The insulating substrate 301 may be a metal substrate (for example, a stainless substrate) having a flattened surface defined by a SiNₓ—SiO₂ multilayer film, a SiO₂ single film, and the like formed thereon. As a result, the heat resistance and shock resistance of the insulating substrate 301 can be improved. This embodiment is preferably applied to organic EL displays because the insulating substrate 301 may not have transparency when being used in organic EL displays.

The insulating substrate 301 may be a plastic substrate having a flat surface defined by a SiO₂ film formed thereon. Further, when a plastic substrate is used as the insulating substrate 301, the TFTs 300a (the single crystal Si substrate 500) and the insulating substrate 301 may be bonded with an adhesive, although the pollution of the single-crystal Si thin film 301a is still concerned.

At the time of the ELA (excimer laser annealing), the bulk Si is separated and so it is necessary to prevent the single-crystal Si layer 335 from being irradiated with the layer. However, this does not need to be considered in the present Embodiment, for example, when the single-crystal Si layer 335 (the single-crystal Si thin film 301a) is formed in a tile (island) pattern on a glass substrate (the insulating substrate 301).

Now referring to FIG. 3-2(f), the single-crystal Si layer 335 is etched or chem-mech polished. As a result, the insulating substrate 301 including the single-crystal Si thin film 301a with a predetermined thickness formed thereon is provided (thinning step).

Then a furnace heat treatment (a first heat treatment step) at 560° C. to 650° C. for 1 to 5 hours (preferably 4 hours or shorter) and RTA (a second heat treatment step) at 650° C. or higher for 10 minutes or shorter are performed. In the first heat treatment step, the hydrogen concentration in Si is reduced, and the defects slightly generated by the hydrogen ion implantation are cured in the second heat treatment step. Thus, the hydrogen atoms can be sufficiently removed from Si, and thermal donor and lattice defects in Si can be completely eliminated. Further, the acceptors can be reactivated. As a result, reproducibility of the transistor characteristics can be improved, and the transistor characteristics can be stabilized. The activation ratio of the acceptors in the single-crystal Si thin film 301a can be 10% (more preferably 25%, and still more preferably 50%) or larger.

The time of the RTA (the second heat treatment step) depends on the heat resistance of the insulating substrate 301 (the glass substrate in the present Embodiment), and it is adjusted within a range where deformation of the insulating substrate 301 is allowed. Specifically, the RTA time needs to become shorter as the treatment temperature is increased. From viewpoint of expansion and contraction or warpage of the substrate 301, the RTA time is preferably as short as possible. The RTA time is commonly determined within a range where no influences are imposed on the insulating substrate 301. In order to improve the device characteristics, it is preferable that the RTA time is as long as possible. The low limit of the RTA time is determined depending on desired device characteristics. When the RTA temperature is 675° C., a reduction in the RTA time by 3 minutes is usually enough to make temperature control difficult, and a variation in device characteristics is increased, although this depends on performances of an apparatus used for the RTA.

The RTA temperature is appropriately determined in accordance with the implanted hydrogen amount and the like. When it is too high, a profile of the impurity (especially boron) is changed. So preferably, the RTA temperature is as low as possible within a range where the impurity profile is not changed, for example, at 850° C. (preferably, 820° C.) or lower. In order to reactivate the acceptors, it is preferable that the RTA temperature is as high as possible and is not lower than 650° C.

Referring to FIG. 3-2 (g), the Poly-Si film 334 and the single-crystal Si thin film 301a are etched into an island pattern by etching. Then, as shown in FIG. 3-3 (h), a gate insulating film (gate oxide film) 302 composed of a SiO₂ film with about 50 nm in thickness is deposited on the entire substrate surface by plasma CVD using a gaseous mixture of SiH₄ and N₂O or a gaseous mixture of TEOS and O₂. Then, a gate electrode 303 is pattern-formed as shown in FIG. 3-3 (i)

Then, the impurity ion-implanting step (involving ion implantation of phosphorus and boron, in FIG. 3-3 (j)), and the impurity ion-activating step are performed. The activation annealing in this activation step may be performed as the short time annealing (for example, RTA at 650° C. or higher for 10 minutes or shorter) in the second heat treatment step. Specifically, after the first heat treatment step, the patterning step for the Poly-Si film 334 and the single-crystal Si thin film 301a, the gate insulating film 302-forming step, and the gate electrode 303-forming step, are performed, and then, the second heat treatment step may be performed.

As shown in FIG. 3-3 (k), a SiN film is formed by plasma CVD using a SiH₄ and N₂O gaseous mixture, and a SiO₂ film is formed by plasma CVD using a TEOS and O₂ gaseous mixture. Thus, an interlayer insulating film 309 composed of a SiN film-SiO₂ film multilayer body is formed.

After formation of contact holes, and a metal wiring 304 (FIG. 3-3 (l)), the single-crystal Si TFTs 300a including the single-crystal Si thin film 301a and the non-single-crystal Si TFTs 300b including the Poly-Si film 334 can be formed.

According to the present Embodiment, the single-crystal Si thin film 301a on the insulating substrate 301 is subjected to the low-temperature and long-time heat treatment and the high-temperature and short-time heat treatment. So the defects in the single-crystal Si thin film 301a can be cured, and the thermal donor in Si can be reduced. Further, the inactivated boron can be activated. As a result, the characteristics of the TFTs 300a including the single-crystal Si thin film 301a can be improved.

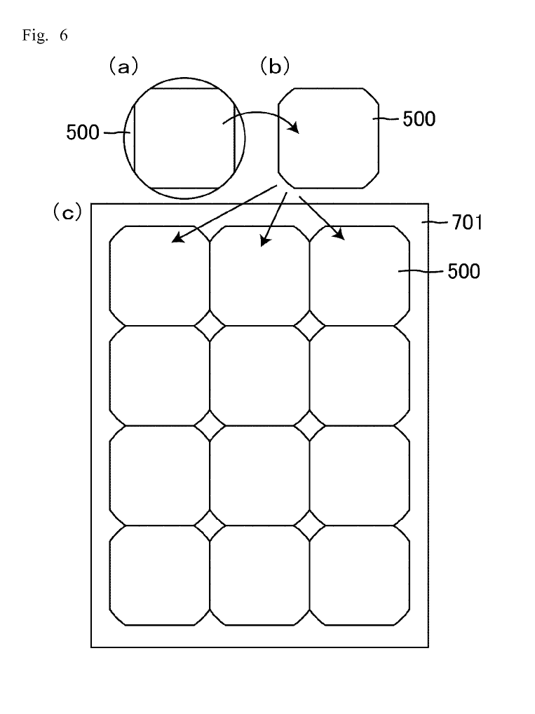

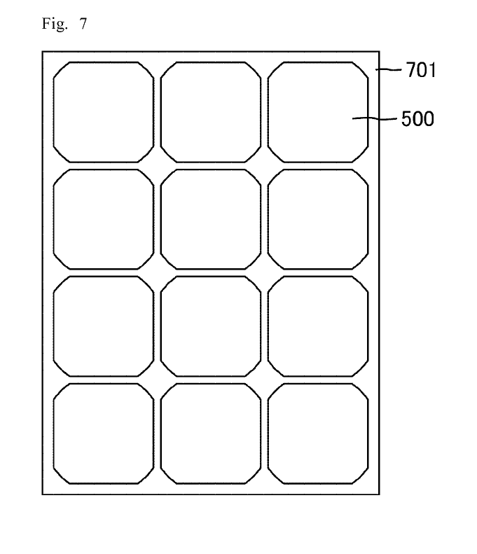

FIGS. 6 (a) to 6 (c), and FIG. 7 are schematic plan views each showing a modified example of Embodiments 2 and 3. Embodiments 2 and 3 are not especially limited to the embodiment in which Si chips are transferred onto portions of an insulating substrate, which is a final substrate. For example, Si wafers 500 having a circular shape as viewed in plane are shaped into a substantially rectangular shape as viewed in plane (FIGS. 6 (a) and 6 (b), and then, the Si wafers 500 may be closely arranged on a large glass substrate 701 in such a manner as shown in FIG. 6 (c). As a result, the variation in display characteristics of the display device can be suppressed, and particularly in current-driving devices such as organic EL displays, display uniformity can be markedly improved. The Si wafers 500 may be arranged without a space as shown in FIG. 6 (c) or with a space as shown in FIG. 7.

### Comparative Embodiment 1

A thin film semiconductor device was produced in the same manner as in Embodiment 1, except that the first heat treatment step was not performed, and RTA was performed at 675° C. for 10 minutes as the second heat treatment step.

### Comparative Embodiment 2

A thin film semiconductor device was produced in the same manner as in Embodiment 1, except that the second heat treatment step was not performed, and a furnace heat treatment was performed at 625° C. for 4 hours as the first heat treatment step.

Table 1 shows S values (subthreshold slope) of produced TFTs of Embodiment 1 and Comparative Embodiments 1 and 2.

TABLE 1

| | | Comparative | Comparative | |
|---|---|---|---|---|
| | | Embodiment 1 | Embodiment 2 | Embodiment 1 |
| Annealing conditions | Furnace annealing | — | 625° C., 4 hr | 600° C., 4 hr |
| | RTA | 675° C., 10 min | — | 675° C., 10 min |
| Transistor | NMOSS value | 116 | 120 | 75 |
| characteristics | PMOSS value | 158 | 136 | 90 |
| (mV/dec) | | | | |

The subthreshold slope (S value) can be measured with a semiconductor parameter analyzer (for example, product of Agilent, 4155C or 4156C) in the following manner. Using this analyzer, gate voltage-dependent drain current values are measured. In a semilog plot of the gate voltage-dependent drain current, a tangent to the curve in the subthreshold region is drawn.

The S value is expressed as the following formula (1), and it is a parameter reflecting defects, localized energy level, and the like in the Si film or the gate oxide film/Si interface, and is influenced by interface charges charged and discharged by a gate electric field due to defects, localized energy level, and the like in the Si film or the gate oxide film/Si interface.

S=(kT/q)ln(10)(1−(C_{OX}+C_{D})/C_{OX}) (1)

where C_{OX} being a gate oxide film capacitance; and C_{D} being a depletion layer capacitance.

The S value increases by addition of localized energy levels in the interface or in the Si crystal to C_{D}. The lower limit of the S value at room temperatures is theoretically 60 mV/dec when C_{D}=0. The closer to 60 mV/dec the S value is, the fewer the defects are.

In Comparative Embodiment 1 where only the high-temperature RTA was performed, the S values were insufficiently recovered. Also in Comparative Embodiment 2 where only the four-hour furnace annealing is performed, the S values were also insufficiently recovered. In contrast, the S values of Embodiment 1 where the furnace annealing and the RTA were both performed were sufficiently recovered although the furnace annealing temperature was performed at a temperature lower than that in Comparative Embodiment 2 by as much as 25° C. This shows that such a two-step thermal treatment is effective in curing of the defects and the like.

The hydrogen concentration needs to be decreased enough for sufficient recovery effects of the RTA (the second heat treatment step). FIG. 4 is a profile of a hydrogen concentration in a Si thin film having been transferred onto a glass substrate, measured by SIMS. In FIG. 4, □ shows a hydrogen concentration at the time of cleavage, and Δ shows a hydrogen concentration after furnace annealing at 650° C. for 5 hours.

As shown in FIG. 4, the hydrogen concentration in the Si thin film is decreased to an average about 4 to 5×10¹⁹ cm⁻³ by the furnace annealing at 650° C. for 5 hours. In such a reduction degree, the characteristics would be sufficiently recovered in the subsequent RTA (the second heat treatment step). Thus the hydrogen concentration in the single-crystal Si thin film after completion of the first heat treatment step in the respective Embodiments is preferably 10²⁰ cm⁻³ or smaller, and more preferably 5×10¹⁹ cm⁻³ or smaller.

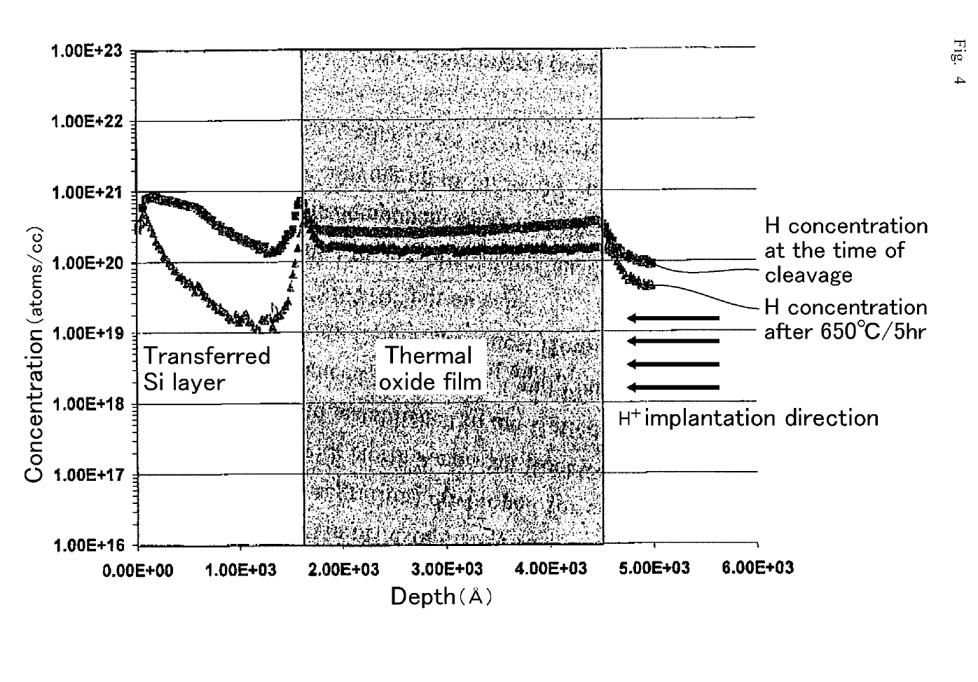

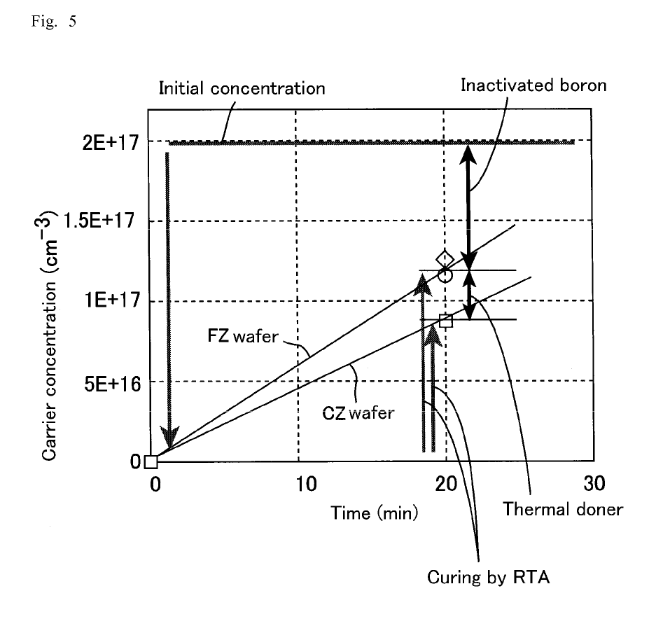

FIG. 5 shows a carrier concentration estimated from Hall effect in the case where RTA at 675° C. for 20 minutes is performed after furnace annealing at 600° C. for 4 hours. A wafer produced by floating zone method (FZ wafer) hardly contains oxygen, so thermal donor is hardly formed. A wafer produced by Czochralski method (CZ wafer) has an oxygen concentration in 10¹⁸ cm⁻³ range, and thermal donors at a high concentration are formed with the help of the hydrogen atoms. So the difference in data between the CZ wafer and the FZ wafer in FIG. 5 would be attributed to the thermal donors. Practically, a thermal treatment at 675° C. for about 10 minutes is allowed in view of glass deformation. FIG. 5 shows that when the RTA is performed at 675° C. for 10 minutes, the doping concentration is reduced to 25% of the initial value. This shows that in order to recover this reduction, acceptors at a concentration about 4 to 5 times higher than the typically needed concentration are previously implanted. In view of a variation in heat treatment conditions or processes, acceptors at a concentration about 5 times higher are preferably implanted. Also in view of safety, acceptors in a concentration about 10 times higher are more preferably implanted.

The present application claims priority to Patent Application No. 2007-337921 filed in Japan on Dec. 27, 2007 under the Paris Convention and provisions of national law in a designated State, the entire contents of which are hereby incorporated by reference.

### BRIEF DESCRIPTION OF DRAWINGS

### [FIG. 1-1]

FIGS. 1-1(a) to 1-1(c) are cross-sectional views each schematically showing a production step of the semiconductor device of Embodiment 1.

### [FIG. 1-2]

FIGS. 1-2(d) to 1-2(f) are cross-sectional views each schematically showing a production step of the semiconductor device of Embodiment 1.

### [FIG. 2-1]

FIGS. 2-1(a) to 2-1(c) are cross-sectional views each schematically showing a production step of the semiconductor device of Embodiment 2.

### [FIG. 2-2]

FIGS. 2-2(d) to 2-2(g) are cross-sectional views each schematically showing a production step of the semiconductor device of Embodiment 2.

### [FIG. 2-3]

FIGS. 2-3(h) to 2-3(l) are cross-sectional views each schematically showing a production step of the semiconductor device of Embodiment 2.

### [FIG. 3-1]

FIGS. 3-1(a) to 3-1(c) are cross-sectional views each schematically showing a production step of the semiconductor device of Embodiment 3.

### [FIG. 3-2]

FIGS. 3-2(d) to 3-2(g) are cross-sectional views each schematically showing a production step of the semiconductor device of Embodiment 3.

### [FIG. 3-3]

FIGS. 3-3(h) to 3-3(l) are cross-sectional views each schematically showing a production step of the semiconductor device of Embodiment 3.

### [FIG. 4]

FIG. 4 is a profile of hydrogen concentration in Si thin film transferred onto the glass substrate, measured by SIMS.

### [FIG. 5]

FIG. 5 is a graph showing carrier concentration estimated from Hall effect in the case where RTA at 675° C. for 20 minutes is performed after furnace annealing at 600° C. for 4 hours.

### [FIG. 6]

FIGS. 6(a) to 6 (c) are plan views schematically showing a modified example of Embodiments 2 and 3.

### [FIG. 7]

FIG. 7 is a plan view schematically showing a modified example of Embodiments 2 and 3.

### EXPLANATION OF NUMERALS AND SYMBOLS

100: Semiconductor device
100a, 200a, 300a: Single-crystal Si TFT
100b, 200b, 300b: Non-single-crystal Si TFT
101, 201, 301: Insulating substrate
101a, 301a: single-crystal Si thin film
101a/C: Channel
101a/SD: Source-drain
101b: Non-single-crystal Si thin film
102a, 113a, 102b, 202, 302: Gate insulating film (gate oxide film)
103a, 112a, 103b, 203, 303: Gate electrode
104, 104a, 204, 304: Metal wiring
105a: Contact
106a: LOCOS oxide film
107: Interlayer flattening film
109b, 208, 209, 308, 309: Interlayer insulating film
108b: Base coat insulating film
110, 111, 210, 310: Flattening film
201a: Strained Si layer
212, 312: SiO₂ film
120, 220, 320: Hydrogen ion-implanted portion (cleavage layer)
231: Graded layer
232: Buffer layer
233, 333: a-Si film
234, 334: Poly-Si film
335: Single-crystal Si layer
500: Single-crystal Si substrate (Si wafer)
502: Strained Si substrate
601: Si wafer
302, 602: Thermal oxide film (bonding layer)
603: Opening
604: Columnar structure
605: Separation structure
606: Wall structure

1. A production method of a semiconductor device including single-crystal semiconductor thin film-including single-crystal semiconductor elements on an insulating substrate,
the production method comprising the successive steps of a first heat treatment step and a second heat treatment step,
wherein in the first heat treatment step,
a single-crystal semiconductor thin film undergoes a heat treatment at lower than 650° C.,
the single-crystal semiconductor thin film containing a doped impurity and including at least part of each one of single-crystal semiconductor elements,
the single-crystal semiconductor thin film bonded to an insulating substrate, and
in the second heat treatment step,
the single-crystal semiconductor thin film undergoes a heat treatment at 650° C. or higher for a time shorter than a treatment time in the first heat treatment step.

2. The production method according to claim 1,
further comprising: before the first heat treatment step,
a bonding step;
a semiconductor substrate-separating step; and
an element-dividing step, in this order,
wherein in the bonding step,
a semiconductor substrate is bonded to the insulating substrate,
the semiconductor substrate containing the doped impurity and including: the at least part of each one of single-crystal semiconductor elements; and a cleavage layer including an implanted cleavage substance containing at least one of hydrogen ion and rare gas ion;
in the semiconductor substrate-separating step,
the semiconductor substrate is separated by cleavage of the cleavage layer by a heat treatment;
in the element-dividing step,
a remaining portion of the semiconductor substrate bonded to the insulating substrate is thinned to give the single-crystal semiconductor thin film, and the semiconductor elements are divided;
in the first heat treatment step,
the single-crystal semiconductor thin film and the insulating substrate undergo the heat treatment; and
in the second heat treatment step,
the single-crystal semiconductor thin film and the insulating substrate undergo the heat treatment.

3. The production method according to claim 1,
further comprising: before the first heat treatment step,
an element-forming step;
a doping step;
an activation step;
a flattening step;
a cleavage layer-forming step;
a bonding step;
a semiconductor substrate-separating step; and
a element-dividing step, in this order,
wherein in the element-forming step,
the at least part of each one of semiconductor elements is formed on a semiconductor substrate;
in the doping step,
the semiconductor substrate is doped with the impurity;
in the activation step,
the impurity in the semiconductor substrate is activated by a heat treatment;
in the flattening step,
a flattening layer is formed on the semiconductor element side-surface of the semiconductor substrate;
in the cleavage layer-forming step,
a cleavage layer is formed by implanting a cleavage substance containing at least one of hydrogen ion and rare gas ion into the semiconductor substrate at a predetermined depth through the flattening layer;
in the bonding step,
the flattening layer of the semiconductor substrate is bonded to the insulating substrate;
in the semiconductor substrate-separating step,
the semiconductor substrate is separated by cleavage of the cleavage layer by a heat treatment;
in the element-dividing step,
a remaining portion of the semiconductor substrate bonded to the insulating substrate is thinned to give the single-crystal semiconductor thin film, and the semiconductor elements are divided;
in the first heat treatment step,
the single-crystal semiconductor thin film and the insulating substrate undergo the heat treatment; and
in the second heat treatment step,
the single-crystal semiconductor thin film and the insulating substrate undergo the heat treatment.

4. The production method of claim 1,
wherein the heat treatment in the first heat treatment step is furnace annealing.

5. The production method of claim 1, wherein the heat treatment in the second heat treatment step is rapid thermal annealing.

6. The production method according to claim 1,
further comprising:
a p-type impurity doping step or p-type impurity doping steps of doping a semiconductor substrate on which the single-crystal semiconductor thin film is to be formed with a p-type impurity; and
an n-type impurity doping step or n-type impurity doping steps of doping the semiconductor substrate with an n-type impurity,
wherein in the p-type impurity doping step or at least one of the p-type impurity doping steps,
the semiconductor substrate is doped with the p-type impurity at a concentration higher than a finally needed impurity concentration, and
in the n-type impurity doping step or at least one of the n-type impurity doping steps,
the semiconductor substrate is doped with the n-type impurity at a concentration lower than a finally needed impurity concentration.

7. The production method according to claim 6,
wherein in the p-type impurity doping step or each of the p-type impurity doping steps,
the semiconductor substrate is doped with the p-type impurity at a concentration higher than a finally needed impurity concentration; and
in the n-type impurity doping step or each of the n-type impurity doping steps,
the semiconductor substrate is doped with the n-type impurity at a concentration lower than a finally needed impurity concentration.

8. The production method according to claim 6,
wherein in the p-type impurity doping step or at least one of the p-type impurity doping steps,
the semiconductor substrate is doped with the p-type impurity at a concentration five times or higher than a finally needed impurity concentration.

9. The production method according to claim 6,
wherein in the p-type impurity doping step or each of the p-type impurity doping steps, the semiconductor substrate is doped with the p-type impurity at a concentration five times or higher than a finally needed impurity concentration.

10. The production method according to claim 1,
wherein the impurity contains boron.

11. A production method of a single-crystal semiconductor thin film-including substrate including an insulating substrate and a single-crystal semiconductor thin film formed on the insulating substrate,
the production method comprising the successive steps of a first heat treatment step and a second heat treatment step,
wherein in the first heat treatment step,
a single-crystal semiconductor thin film bonded to an insulating substrate undergoes a heat treatment at lower than 650° C., and
in the second heat treatment step,
the single-crystal semiconductor thin film undergoes a heat treatment at 650° C. or higher for a time shorter than a treatment time in the first heat treatment step.

12. The production method according to claim 11,
further comprising: before the first heat treatment step,
a bonding step;
a semiconductor substrate-separating step; and
a thinning step in this order,
wherein in the bonding step,
a semiconductor substrate including a cleavage layer containing an implanted cleavage substance containing at least one of hydrogen ion and rare gas ion is bonded to the insulating substrate;
in the semiconductor substrate-separating step,
the semiconductor substrate is separated by cleavage of the cleavage layer by a heat treatment;
in the thinning step,
a remaining portion of the semiconductor substrate bonded to the insulating substrate is thinned to give the single-crystal semiconductor thin film;
in the first heat treatment step,
the single-crystal semiconductor thin film and the insulating substrate undergo the heat treatment; and
in the second heat treatment step,
the single-crystal semiconductor thin film and the insulating substrate undergo the heat treatment.

13. The production method according to claim 11, further comprising: before the first heat treatment step,
a cleavage layer-forming step;
a bonding step;
a semiconductor substrate-separating step; and
a thinning step in this order,
wherein in the cleavage layer-forming step,
a cleavage layer is formed by implanting a cleavage substance containing at least one of hydrogen ion and rare gas ion into a semiconductor substrate at a predetermined depth;
in the bonding step,
the semiconductor substrate is bonded to the insulating substrate;
in the semiconductor substrate-separating step,
the semiconductor substrate is separated by cleavage of the cleavage layer by a heat treatment;
in the thinning step,
a remaining portion of the semiconductor substrate bonded to the insulating substrate is thinned to give the single-crystal semiconductor thin film;
in the first heat treatment step,
the single-crystal semiconductor thin film and the insulating substrate undergo the heat treatment; and
in the second heat treatment step,
the single-crystal semiconductor thin film and the insulating substrate undergo the heat treatment.

14. The production method according to claim 11,
wherein the heat treatment in the first heat treatment step is furnace annealing.

15. The production method according to claim 11,
wherein the heat treatment in the second heat treatment is rapid thermal annealing.

16. The production method according to claim 11,
further comprising:
a strained semiconductor layer-including substrate-forming step;
a cleavage layer-forming step;
a bonding step;
a strained semiconductor layer-including substrate-separating step; and
a thinning step in this order,
wherein in the strained semiconductor layer-including substrate-forming step,
a strained semiconductor layer-including substrate is formed by preparing a graded layer, a buffer layer, and a strained semiconductor layer by epitaxial growth on a semiconductor substrate in this order from the semiconductor substrate side;
in the cleavage layer-forming step,
a cleavage layer is formed by implanting a cleavage substance containing at least one of hydrogen ion and rare gas ion into a region of at least one of the graded layer and the buffer layer of the strained semiconductor layer-including substrate;
in the bonding step,
the strained semiconductor layer-including substrate is bonded to the insulating substrate;
in the strained semiconductor layer-including substrate-separating step,
the strained semiconductor layer-including substrate is separated by cleavage of the cleavage layer by a heat treatment; and
in the thinning step,
at least the buffer layer of the strained semiconductor layer-including substrate bonded to the insulating substrate is removed by etching to give the single-crystal semiconductor thin film including the strained semiconductor layer.

17. The production method according to claim 11,
wherein the single-crystal semiconductor thin film is formed by epitaxial growth or floating zone.

18. A semiconductor device comprising single-crystal semiconductor elements produced using a single-crystal semiconductor thin film-including substrate produced by the production method of claim 11.

19. A semiconductor device comprising single-crystal semiconductor thin film-including single-crystal semiconductor elements on an insulating substrate,
wherein the insulating substrate has a heat-resistant temperature of 600° C. or lower.

20. The semiconductor device according to claim 19,
wherein an activation ratio of acceptors in the single-crystal semiconductor thin film is 10% or larger.

21. The semiconductor device according to claim 19,
wherein the insulating substrate has a strain point of 800° C. or lower.

22. The semiconductor device according to claim 19,
wherein the insulating substrate is a glass substrate.

23. The semiconductor device according to claim 19,
wherein a subthreshold slope of the single-crystal semiconductor elements is 75 mV/dec or smaller.

24. The semiconductor device according to claim 19,
further comprising non-single-crystal semiconductor thin film-including non-single-crystal semiconductor elements on the insulating substrate.

25. The semiconductor device according to claim 19,
wherein the insulating substrate is larger than a region where the single-crystal semiconductor elements are arranged.

26. The semiconductor device according to claim 25,
wherein the semiconductor device includes a plurality of the regions, and
the regions are closely arranged in an island pattern in a plane of the insulating substrate.

27. The semiconductor device according to claim 19,
wherein the single-crystal semiconductor thin film contains strained silicon.

28. The semiconductor device according to claim 19,
wherein the single-crystal semiconductor thin film is formed by epitaxial growth or floating zone.

29. The semiconductor device according to claim 19,
wherein the single-crystal semiconductor thin film contains at least one semiconductor selected from the group consisting of germanium, silicon carbide, and gallium nitride.

30. The semiconductor device according to claim 19,
wherein the single-crystal semiconductor thin film has an oxygen concentration of 10¹⁸/cm³ or lower.

31. The semiconductor device according to claim 19,
wherein a bonded interface between the insulating substrate and the single-crystal semiconductor elements contains SiO₂—SiO₂ bond or SiO₂-glass bond.

32. A single-crystal semiconductor thin film-including substrate comprising a single-crystal semiconductor thin film on an insulating substrate,
wherein the insulating substrate has a heat-resistant temperature of 600° C. or lower.

33. The single-crystal semiconductor thin film-including substrate according to claim 32,
wherein the insulating substrate has a strain point of 800° C. or lower.

34. The single-crystal semiconductor thin film-including substrate according to claim 32,
wherein the insulating substrate is a glass substrate.

35. The single-crystal semiconductor thin film-including substrate according to claim 32,
further comprising a non-single-crystal semiconductor thin film on the insulating substrate.

36. The single-crystal semiconductor thin film-including substrate according to claim 32,
wherein the insulating substrate is larger than the single-crystal semiconductor thin film.

37. The single-crystal semiconductor thin film-including substrate according to claim 36,
comprising a plurality of the single-crystal semiconductor thin films, and
the single-crystal semiconductor thin films are closely arranged in an island pattern in a plane of the insulating substrate.

38. The single-crystal semiconductor thin film-including substrate according to claim 32,
wherein the single-crystal semiconductor thin film contains strained silicon.

39. The single-crystal semiconductor thin film-including substrate according to claim 32,
wherein the single-crystal semiconductor thin film is formed by epitaxial growth or floating zone.

40. The single-crystal semiconductor thin film-including substrate according to claim 32,
wherein the single-crystal semiconductor thin film contains at least one semiconductor selected from the group consisting of germanium, silicon carbide, and gallium nitride.

41. The single-crystal semiconductor thin film-including substrate according to claim 32,
wherein the single-crystal semiconductor thin film has an oxygen concentration of 10¹⁸/cm³ or lower.

42. The single-crystal semiconductor thin film-including substrate according to claim 32,
wherein a bonded interface between the insulating substrate and the single-crystal semiconductor thin film contains SiO₂—SiO₂ bond or SiO₂-glass bond.

43. A semiconductor device comprising single-crystal semiconductor elements produced using the single-crystal semiconductor thin film-including substrate according to claim 32.
